(19) United States
(12) Patent Application Publication
(10) Pub. No.: US 2025/0089494 A1
(43) Pub. Date: Mar. 13, 2025

(54) ARRAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Yonglin Guo, Beijing (CN); Gukhwan Song, Beijing (CN); Ming Hu, Beijing (CN); Miao Wang, Beijing (CN); Wenhui Gao, Beijing (CN); Cong Liu, Beijing (CN); Binyan Wang, Beijing (CN); Youngjang Lee, Beijing (CN); Dan Cao, Beijing (CN); Jingwen Zhang, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/576,036

(22) PCT Filed: Feb. 28, 2023
(86) PCT No.: PCT/CN2023/078575

§ 371 Date: Jan. 2, 2024

(51) Int. Cl. H10K 59/131; H10K 59/122; H10K 59/123

(52) U.S. Cl. CPC H10K 59/131; H10K 59/122; H10K 59/123

(57) ABSTRACT

An array substrate is provided. The array substrate includes a plurality of data lines; a plurality of second fanout connecting lines; and a plurality of first voltage supply lines. In at least one subpixel of the array substrate, an individual data line of the plurality of data lines and an individual second fanout connecting line of the plurality of second fanout connecting lines have a substantial mirror symmetry with respect to an individual first voltage supply fine of the plurality of first voltage supply lines.

### TECHNICAL FIELD

The present invention relates to display technology, more particularly, to an array substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a plurality of data lines; a plurality of second fanout connecting lines; and a plurality of first voltage supply lines; wherein, in at least one subpixel of the array substrate, an individual data line of the plurality of data lines and an individual second fanout connecting line of the plurality of second fanout connecting lines have a substantial mirror symmetry with respect to an individual first voltage supply line of the plurality of first voltage supply lines.

Optionally, the plurality of data lines, the plurality of second fanout connecting lines, and the plurality of first voltage supply lines are in a same layer.

Optionally, the array substrate further comprises an anode on a side of the plurality of data lines, the plurality of second fanout connecting lines, and the plurality of first voltage supply lines away from a base substrate; wherein an orthographic projection of the anode on a base substrate at least partially overlaps with an orthographic projection of the individual second fanout connecting line on the base substrate; at least partially overlaps with an orthographic projection of the individual first voltage supply line on the base substrate; and at least partially overlaps with an orthographic projection of an individual data line on the base substrate.

Optionally, the individual second fanout connecting line, the individual first voltage supply line, and the individual data line are substantially evenly distributed along a first direction with respect to the anode.

Optionally, portions of the individual second fanout connecting line, the individual first voltage supply line, and the individual data line, in a region crossing over the anode, have a substantial mirror symmetry with respect to a plane perpendicular to the anode and intersecting the anode.

Optionally, the array substrate further comprises a first data signal connecting pad, a second data signal connecting pad, and a fanout connecting pad; wherein the individual data line is connected to the second data signal connecting pad through a first pad connecting via; the individual second fanout connecting line is connected to the fanout connecting pad through a second pad connecting via; and the second data signal connecting pad is connected to the first data signal connecting pad through a third pad connecting via.

Optionally, an orthographic projection of a conductive material extending through the first pad connecting via on a base substrate is substantially non-overlapping with an orthographic projection of a conductive material extending through the third pad connecting via on the base substrate.

Optionally, the first pad connecting via has a first elongated shape in a cross-section along a plane having the plurality of data lines, the plurality of first voltage supply lines, and the plurality of second fanout connecting lines; the second pad connecting via has a second elongated shape in a cross-section along a plane having the plurality of data lines, the plurality of first voltage supply lines, and the plurality of second fanout connecting lines; the third pad connecting via has a third elongated shape in a cross-section along a plane having the plurality of data lines, the plurality of first voltage supply lines, and the plurality of second fanout connecting lines; the first elongated shape has a longitudinal side along a direction substantially parallel to a first direction; the second elongated shape has a longitudinal side along a direction substantially parallel to the first direction; and the third elongated shape has a longitudinal side along a direction substantially parallel to a second direction.

Optionally, the array substrate further comprises a pixel definition layer; wherein an orthographic projection of a pixel definition layer on a base substrate covers an orthographic projection of a conductive material extending through the first pad connecting via on the base substrate, and covers an orthographic projection of a conductive material extending through the second pad connecting via on the base substrate.

Optionally, the array substrate further comprises a pixel definition layer defining a plurality of subpixel apertures, and a light emitting layer in the plurality of subpixel apertures; wherein an orthographic projection of a light emitting material in the plurality of subpixel apertures on a base substrate is substantially non-overlapping with the orthographic projection of a conductive material extending through the first pad connecting via on the base substrate, and is non-overlapping with the orthographic projection of a conductive material extending through the second pad connecting via on the base substrate.

Optionally, the array substrate further comprises an anode, an anode connecting pad, a second relay electrode, and a first relay electrode; a first anode connecting via, a second anode connecting via, a third anode connecting via, and a fourth anode connecting via; and a pixel driving circuit comprising a light emitting control transistor; wherein the anode is connected to the anode connecting pad through the first anode connecting via; the anode connecting pad is connected to the second relay electrode through the second anode connecting via; the second relay electrode is connected to the first relay electrode through the third anode connecting via; and the first relay electrode is connected to a second electrode of the light emitting control transistor through the fourth anode connecting via.

Optionally, in a first adjacent column of pixel driving circuits, the first anode connecting via is spaced apart from the fourth anode connecting via by a first distance along a second direction; in a second adjacent column of pixel driving circuits, the first anode connecting via is spaced apart from the fourth anode connecting via by a second distance along the second direction; and the second distance is greater than the first distance by at least 10%.

Optionally, in a first adjacent column of pixel driving circuits, an orthographic projection of the anode on a base substrate substantially covers the orthographic projection of the anode connecting pad on a base substrate, substantially covers the orthographic projection of the second relay electrode on the base substrate, and substantially covers the orthographic projection of the first relay electrode on the base substrate; and in a second adjacent column of pixel driving circuits, an orthographic projection of the anode on the base substrate partially overlaps with an orthographic projection of the anode connecting pad on the base substrate, is substantially non-overlapping with the orthographic projection of the second relay electrode on the base substrate, and is substantially non-overlapping with the orthographic projection of the first relay electrode on the base substrate.

Optionally, the array substrate further comprises, in a first adjacent column of pixel driving circuits, a respective reference signal line of a plurality of reference signal lines; and, in a second adjacent column of pixel driving circuits, a respective third reset signal line of a plurality of third reset signal lines; wherein the plurality of reference signal lines are absent in the second adjacent column of pixel driving circuits; and the plurality of third reset signal lines are absent in the first adjacent column of pixel driving circuits.

Optionally, the array substrate further comprises a node connecting line in a respective pixel driving circuit; wherein, in the first adjacent column of pixel driving circuits, the node connecting line is at least partially surrounded by the respective reference signal line.

Optionally, in the first adjacent column of pixel driving circuits, the respective reference signal line comprises a main body extending along a direction substantially parallel to a second direction, and a plurality of first reference signal branches; a respective first reference signal branch of the plurality of first reference signal branches extends away from the main body: the respective first reference signal branch comprises a first portion and a second portion; the first portion connects the second portion with the main body; the first portion extends along a direction substantially parallel to a first direction; the second portion extends along a direction substantially parallel to the second direction; and the node connecting line is at least partially surrounded by the main body on a first side, by the first portion on a second side, and by the second portion on a third side.

Optionally, in the second adjacent column of pixel driving circuits, the node connecting line is at least partially surrounded by the respective third reset signal line on a first side, and at least partially surrounded by a first voltage signal connecting pad on a second side.

Optionally, the array substrate further comprises a plurality of first fanout connecting lines, a second data signal connecting pad, a fanout connecting pad, a first connecting bridge, and a second connecting bridge; wherein the plurality of data lines comprises a plurality of second data lines; a respective second data line of the plurality of second data lines is connected to the second data signal connecting pad; the second data signal connecting pad is connected to the second connecting bridge; the second connecting bridge is connected to a respective first fanout connecting line of the plurality of first fanout connecting lines; the respective first fanout connecting line is connected to the first connecting bridge: the first connecting bridge is connected to a respective second fanout connecting line of the plurality of second fanout connecting lines; and the respective second fanout connecting line is electrically connected to a data driving circuit.

Optionally, an orthographic projection of the respective second fanout connecting line of the plurality of second fanout connecting lines on a base substrate substantially covers an orthographic projection of the first connecting bridge on a base substrate; an orthographic projection of the respective second data line of the plurality of second data lines on the base substrate substantially covers an orthographic projection of the second connecting bridge on the base substrate; in at least one column of subpixels, an individual second fanout connecting line of the plurality of second fanout connecting lines is disconnected from an individual second voltage supply line of a plurality of second voltage supply lines by a line break; an insulating material of an insulating layer is in the line break; and an orthographic projection of an individual first fanout connecting line of the plurality of first fanout connecting lines on the base substrate substantially covers an orthographic projection of the insulating material in the line break on the base substrate.

In another aspect, the present disclosure provides an array substrate, comprising a plurality of data lines; a plurality of first fanout connecting lines; a plurality of second fanout connecting lines; and a plurality of first voltage supply lines; wherein, in at least one subpixel of the array substrate, an individual data line of the plurality of data lines and an individual second fanout connecting line of the plurality of second fanout connecting lines have a substantial mirror symmetry with respect to an individual first voltage supply line of the plurality of first voltage supply lines; the plurality of first fanout connecting lines and the plurality of second fanout connecting lines are substantially in a display area of the array substrate; the plurality of data lines comprise a plurality of first data lines and a plurality of second data lines; the plurality of first data lines are connected to a data driving circuit; and a respective second data line of the plurality of second data lines is connected to the data driving circuit through a respective first fanout connecting line of the plurality of first fanout connecting lines and a respective second fanout connecting line of the plurality of second fanout connecting lines.

In another aspect, the present disclosure provides a display apparatus, comprising the array substrate described herein or fabricated by a method described herein, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2A is a circuit diagram illustrating the structure of a pixel driving circuit in some embodiments according to the present disclosure.

FIG. 2B is a circuit diagram illustrating the structure of a pixel driving circuit in some embodiments according to the present disclosure.

FIG. 2C is a circuit diagram illustrating the structure of a pixel driving circuit in some embodiments according to the present disclosure.

FIG. 2D is a circuit diagram illustrating the structure of a pixel driving circuit in some embodiments according to the present disclosure.

FIG. 2E is a timing diagram illustrating the operation of a pixel driving circuit in some embodiments according to the present disclosure.

FIG. 3A is a diagram illustrating the structure of an array substrate in some embodiments according to the present disclosure.

FIG. 3B is a schematic diagram illustrating an arrangement of a plurality of pixel driving circuits in an array substrate depicted in FIG. 3A.

FIG. 3C is a diagram illustrating the structure of a semiconductor material layer in an array substrate depicted in FIG. 3A.

FIG. 3D is a diagram illustrating the structure of a first conductive layer in an array substrate depicted in FIG. 3A.

FIG. 3E is a diagram illustrating the structure of a second conductive layer in an array substrate depicted in FIG. 3A.

FIG. 3F is a diagram illustrating the structure of an inter-layer dielectric layer in an array substrate depicted in FIG. 3A.

FIG. 3G is a diagram illustrating the structure of a first signal line layer in an array substrate depicted in FIG. 3A.

FIG. 3H is a diagram illustrating the structure of a first planarization layer in an array substrate depicted in FIG. 3A.

FIG. 3I is a diagram illustrating the structure of a second signal line layer in an array substrate depicted in FIG. 3A.

FIG. 3J is a diagram illustrating the structure of a second planarization layer in an array substrate depicted in FIG. 3A.

| FIG. 3K is a diagram illustrating the structure of a third signal line layer in an array substrate depicted in FIG. 3A.

FIG. 3L is a diagram illustrating the structure of a third planarization layer in an array substrate depicted in FIG. 3A.

FIG. 3M is a diagram illustrating the structure of an anode layer in an array substrate depicted in FIG. 3A.

FIG. 3N is a diagram illustrating the structure of a pixel definition layer in an array substrate depicted in FIG. 3A.

FIG. 4A is a cross-sectional view along an A-A′ line in FIG. 3A.

FIG. 4B is a cross-sectional view along a B-B′ line in FIG. 3A.

FIG. 5 illustrates a layout of signal lines in an array substrate in some embodiments according to the present disclosure.

FIG. 6A illustrates a layout of signal lines in a portion of an array substrate in some embodiments according to the present disclosure.

FIG. 6B illustrates a layout of a plurality of first data lines in the portion of the array substrate depicted in FIG. 6A.

FIG. 6C illustrates a layout of a plurality of second data lines, a plurality of first fanout connecting lines, and a plurality of second fanout connecting lines in the portion of the array substrate depicted in FIG. 6A.

FIG. 6D illustrates a layout of signal lines not involved in data signal transmission in the portion of the array substrate depicted in FIG. 6A.

FIG. 7 illustrates a layout of signal lines not involved in data signal transmission in the array substrate depicted in FIG. 5.

FIG. 8 illustrates a layout of signal lines in a second signal line layer and a third signal line layer in a portion of an array substrate in some embodiments according to the present disclosure.

FIG. 9 illustrates a layout of signal lines in a first signal line layer, a second signal line layer, and a third signal line layer in a portion of an array substrate in some embodiments according to the present disclosure.

FIG. 10 illustrates a layout of signal lines in a first signal line layer in a portion of an array substrate in some embodiments according to the present disclosure.

FIG. 11 illustrates the structure of an interconnected reset network in some embodiments according to the present disclosure.

FIG. 12 illustrates a layout of signal lines in a third signal line layer and an anode layer in a portion of an array substrate in some embodiments according to the present disclosure.

FIG. 13 illustrates connections between signal lines in a third signal line layer and underlying pads through pad connecting vias in a portion of an array substrate in some embodiments according to the present disclosure.

FIG. 14A illustrates pad connecting vias, an anode layer, and a pixel definition layer in a portion of an array substrate in some embodiments according to the present disclosure.

FIG. 14B illustrates pad connecting vias, an anode layer, and a pixel definition layer in a portion of an array substrate in some embodiments according to the present disclosure.

FIG. 15 illustrates connections between an anode connecting pad, a first relay electrode, and a second relay electrode in a portion of an array substrate in some embodiments according to the present disclosure.

FIG. 16 illustrates connections between an anode, an anode connecting pad, a first relay electrode, and a second relay electrode in a portion of an array substrate in some embodiments according to the present disclosure.

FIG. 17 illustrates a layout of signal lines involved in data signal transmission to a respective second data line of a plurality of second data lines in a portion of an array substrate in some embodiments according to the present disclosure.

FIG. 18 illustrates a layout of signal lines in a second signal line layer involved in data signal transmission to a respective second data line of a plurality of second data lines in a portion of an array substrate in some embodiments according to the present disclosure.

FIG. 19 illustrates a layout of signal lines in a third signal line layer involved in data signal transmission to a respective second data line of a plurality of second data lines in a portion of an array substrate in some embodiments according to the present disclosure.

FIG. 20 is a diagram illustrating the structure of a semiconductor material layer and a second conductive layer in an array substrate in some embodiments according to the present disclosure.

FIG. 21 is a diagram illustrating the structure of a semiconductor material layer and a respective light emitting control signal line, and a second node connecting line in an array substrate in some embodiments according to the present disclosure.

FIG. 22A is a diagram illustrating the structure of a first signal line layer in an array substrate in some embodiments according to the present disclosure.

FIG. 22B is a diagram illustrating the structure of a second signal line layer in an array substrate in some embodiments according to the present disclosure.

FIG. 22C illustrates pad connecting vias, an anode layer, and a pixel definition layer in a portion of an array substrate in some embodiments according to the present disclosure.

FIG. 23A is a diagram illustrating the structure of a second signal line layer in an array substrate in some embodiments according to the present disclosure.

FIG. 23B is a diagram illustrating the structure of a third signal line layer in an array substrate in some embodiments according to the present disclosure.

FIG. 23C is a diagram illustrating the structure of a second signal line layer and a third signal line layer in an array substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a plurality of data lines; a plurality of second fanout connecting lines; and a plurality of first voltage supply lines. Optionally, in at least one subpixel of the array substrate, an individual data line of the plurality of data lines and an individual second fanout connecting line of the plurality of second fanout connecting lines have a substantial mirror symmetry with respect to an individual first voltage supply line of the plurality of first voltage supply lines.

Various appropriate pixel driving circuits may be used in the present array substrate. Examples of appropriate driving circuits include 3T1C, 2T1C, 4T1C, 4T2C, 5T2C, 6T1C, 7T1C, 7T2C, 8T1C, and 8T2C. In some embodiments, the respective one of the plurality of pixel driving circuits is a 7T1C driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

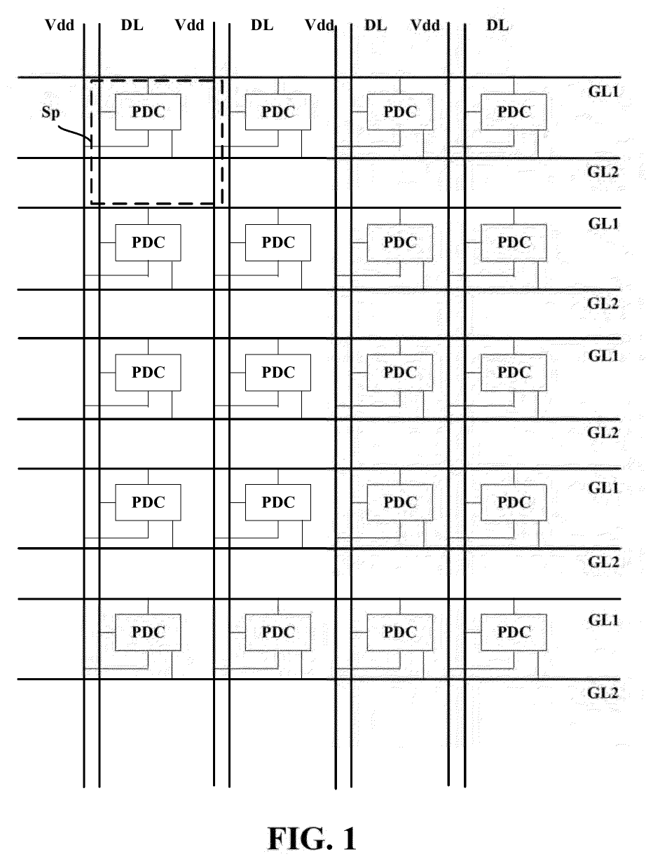

FIG. 1 is a plan view of an array substrate in some embodiments according to the present disclosure. Referring to FIG. 1, the array substrate includes an array of subpixels Sp. Each subpixel includes an electronic component, e.g., a light emitting element. In one example, the light emitting element is driven by a respective pixel driving circuit PDC. The array substrate includes a plurality of first gate lines GL1, a plurality of second gate lines GL2, a plurality of data lines DL, a plurality of first voltage supply line Vdd, and a respective second voltage supply line (e.g., a low voltage supply line). Light emission in a respective subpixel Sp is driven by a respective pixel driving circuit PDC. In one example, a high voltage signal (e.g., a VDD signal) is input, through the respective first voltage supply line of the plurality of first voltage supply line Vdd, to the respective pixel driving circuit PDC connected to an anode of the light emitting element; a low voltage signal (e.g., a VSS signal) is input, through a low voltage supply line, to a cathode of the light emitting element. A voltage difference between the high voltage signal (e.g., the VDD signal) and the low voltage signal (e.g., the VSS signal) is a driving voltage ΔV that drives light emission in the light emitting element.

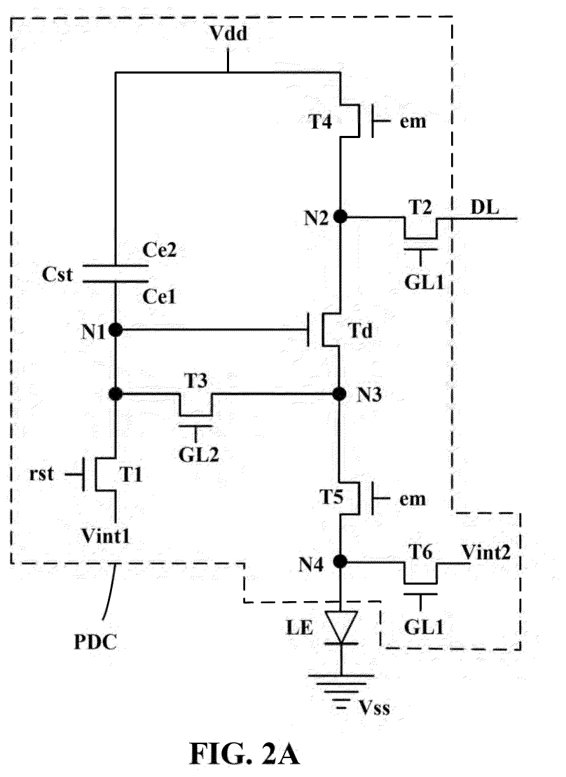

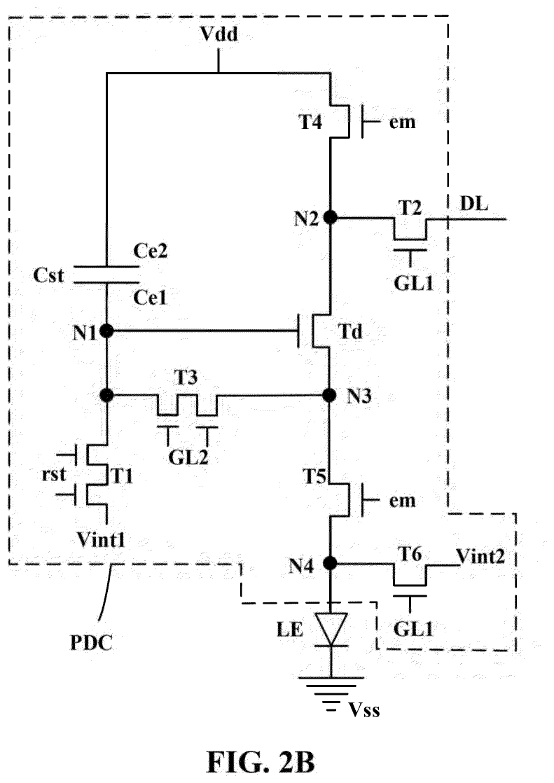

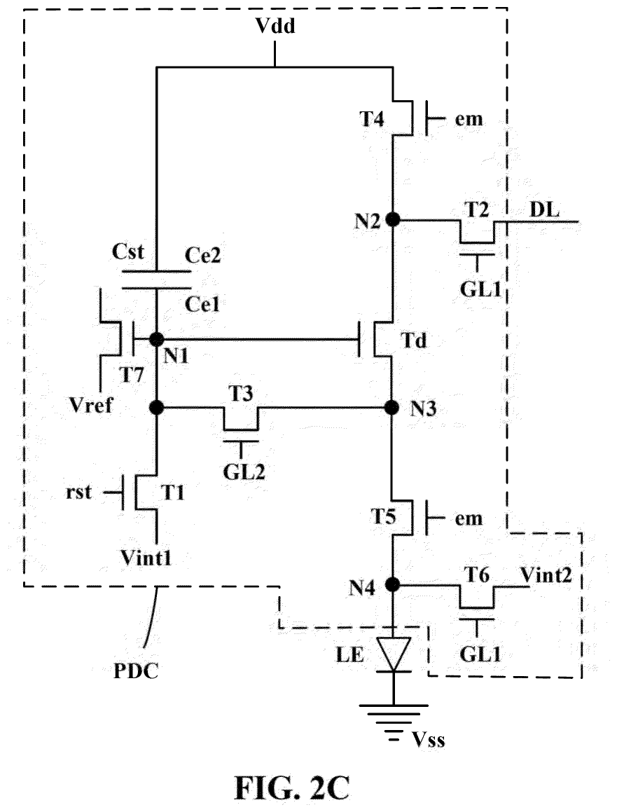

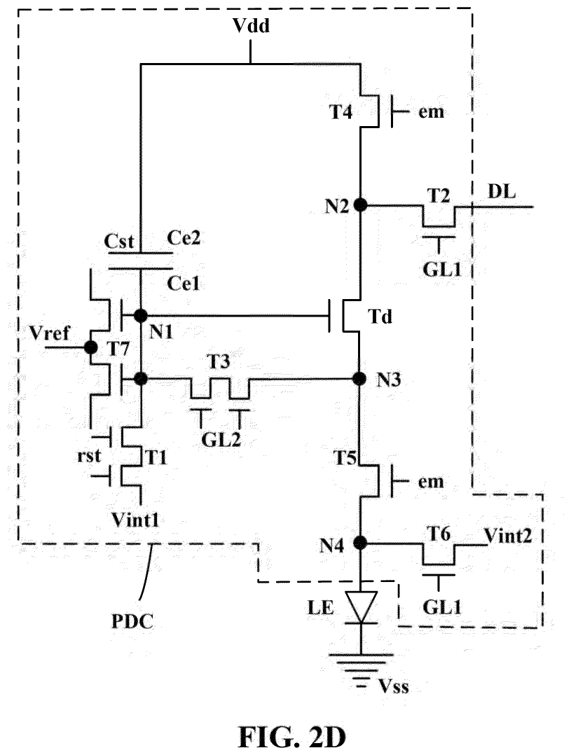

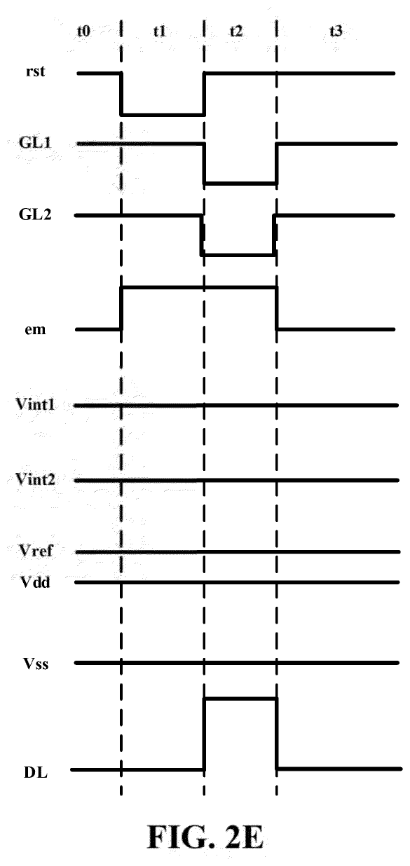

FIG. 2A is a circuit diagram illustrating the structure of a pixel driving circuit in some embodiments according to the present disclosure. Referring to FIG. 2A, in some embodiments, the respective pixel driving circuit includes a driving transistor Td; a storage capacitor Cst having a first capacitor electrode Ce1 and a second capacitor electrode Ce2; a first transistor T1 having a gate electrode connected to a respective reset control signal line of a plurality of reset control signal lines rst, a first electrode connected to a respective first reset signal line of a plurality of first reset signal lines Vint1, and a second electrode connected to a first capacitor electrode Ce1 of the storage capacitor Cst and a gate electrode of the driving transistor Td: a second transistor T2 having a gate electrode connected to a respective first gate line of a plurality of first gate lines GL1, a first electrode connected to a respective data line of a plurality of data lines DL, and a second electrode connected to a first electrode of the driving transistor Td; a third transistor T3 having a gate electrode connected to the respective second gate line of a plurality of second gate lines GL2, a first electrode connected to the first capacitor electrode Ce1 of the storage capacitor Cst and the gate electrode of the driving transistor Td, and a second electrode connected to a second electrode of the driving transistor Td; a fourth transistor T4 having a gate electrode connected to a respective light emitting control signal line of a plurality of light emitting control signal lines em, a first electrode connected to a respective first voltage supply line of a plurality of first voltage supply lines Vdd, and a second electrode connected to the first electrode of the driving transistor Td and the second electrode of the second transistor T2; a fifth transistor T5 having a gate electrode connected to the respective light emitting control signal line, a first electrode connected to second electrodes of the driving transistor Td and the third transistor T3, and a second electrode connected to an anode of a light emitting element LE; and a sixth transistor T6 having a gate electrode connected to the respective first gate line of the plurality of first gate lines GL1, a first electrode connected to a respective second reset signal line of the plurality of second reset signal lines Vint2, and a second electrode connected to the second electrode of the fifth transistor and the anode of the light emitting element LE. The second capacitor electrode Ce2 is connected to the respective first voltage supply line and the first electrode of the fourth transistor T4.

FIG. 2B is a circuit diagram illustrating the structure of a pixel driving circuit in some embodiments according to the present disclosure. Referring to FIG. 2B, in some embodiments, the third transistor T3 is a “double gate” transistor, and the first transistor T1 is a “double gate” transistor. Optionally, in a “double gate” first transistor, the active layer of the first transistor crosses over a respective reset control signal lines twice (alternatively, the respective reset control signal line crosses over the active layer of the first transistor T1 twice). Similarly, in a “double gate” third transistor, the active layer of the third transistor T3 crosses over a respective first gate line of the plurality of first gate lines GL1 twice (alternatively, the respective gate line crosses over the active layer of the third transistor T3 twice).

The pixel driving circuit further include a first node N1, a second node N2, a third node N3, and a fourth node N4. The first node N1 is connected to the gate electrode of the driving transistor Td, the first capacitor electrode Ce1, and the first electrode of the third transistor T3. The second node N2 is connected to the second electrode of the fourth transistor T4, the second electrode of the second transistor T2, and the first electrode of the driving transistor Td. The third node N3 is connected to the second electrode of the driving transistor Td, the second electrode of the third transistor T3, and the first electrode of the fifth transistor T5. The fourth node N4 is connected to the second electrode of the fifth transistor T5, the second electrode of the sixth transistor T6 and the anode of the light emitting element LE.

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor, in one example, the first electrode is configured to receive an input signal and the second electrode is configured to output an output signal; in another example, the second electrode is configured to receive an input signal and the first electrode is configured to output an output signal.

FIG. 2C is a circuit diagram illustrating the structure of a pixel driving circuit in some embodiments according to the present disclosure. Referring to FIG. 2C, in some embodiments, the respective pixel driving circuit includes a driving transistor Td; a storage capacitor Cst having a first capacitor electrode Ce1 and a second capacitor electrode Ce2; a first transistor T1 having a gate electrode connected to a respective reset control signal line of a plurality of reset control signal lines rst, a first electrode connected to a respective first reset signal line of a plurality of first reset signal lines Vint1, and a second electrode connected to a first capacitor electrode Ce1 of the storage capacitor Cst and a gate electrode of the driving transistor Td; a second transistor T2 having a gate electrode connected to a respective first gate line of a plurality of first gate lines GL1, a first electrode connected to a respective data line of a plurality of data lines DL, and a second electrode connected to a first electrode of the driving transistor Td; a third transistor T3 having a gate electrode connected to the respective second gate line of a plurality of second gate lines GL2, a first electrode connected to the first capacitor electrode Ce1 of the storage capacitor Cst and the gate electrode of the driving transistor Td, and a second electrode connected to a second electrode of the driving transistor Td; a fourth transistor T4 having a gate electrode connected to a respective light emitting control signal line of a plurality of light emitting control signal lines em, a first electrode connected to a respective first voltage supply line of a plurality of first voltage supply lines Vdd, and a second electrode connected to the first electrode of the driving transistor Td and the second electrode of the second transistor T2; a fifth transistor T5 having a gate electrode connected to the respective light emitting control signal line, a first electrode connected to second electrodes of the driving transistor Td and the third transistor 13, and a second electrode connected to an anode of a light emitting element LE; a sixth transistor T6 having a gate electrode connected to the respective first gate line of the plurality of first gate lines GL1, a first electrode connected to a respective second reset signal line of the plurality of second reset signal lines Vint2, and a second electrode connected to the second electrode of the fifth transistor and the anode of the light emitting element LE; and a seventh transistor T7 having a gate electrode connected to the gate electrode of the driving transistor Td, a first electrode connected to a reference signal line Vref, and a second electrode that is floating. The second capacitor electrode Ce2 is connected to the respective first voltage supply line and the first electrode of the fourth transistor T4. Optionally, at least a portion of the first capacitor electrode Ce1 is the gate electrode of the seventh transistor T7, and at least another portion of the first capacitor electrode Ce1 is the gate electrode of the driving transistor Td. In one example, the reference signal line Vref is configured to provide a first level voltage signal (e.g., a low-level voltage signal) during at least a light emitting sub-phase of one frame of image. In another example, the reference signal line Vref is configured to provide a second level voltage signal (e.g., a high-level voltage signal) during at least a light emitting sub-phase of one frame of image. In one example, the reference signal line Vref is configured to provide a reset signal.

The inventors of the present disclosure discover that, by having the seventh transistor T7, the voltage level at the node N1 can be effectively stabilized. The inventors of the present disclosure discover that an unstable voltage level at the node N1 leads to flicker defect in the array substrate. By having the seventh transistor T7, the leakage at the gate electrode of the seventh transistor T7 can effectively stabilize the voltage level at the node N1. The inventors of the present disclosure discover that this unique structure is particularly conducive to low frequency display.

FIG. 2D is a circuit diagram illustrating the structure of a pixel driving circuit in some embodiments according to the present disclosure. Referring to FIG. 2D, in some embodiments, the seventh transistor T7 is a “double gate” transistor, the third transistor T3 is a “double gate” transistor, and the first transistor T1 is a “double gate” transistor. Optionally, in a “double gate” first transistor, the active layer of the first transistor crosses over a respective reset control signal lines twice (alternatively, the respective reset control signal line crosses over the active layer of the first transistor T1 twice). Similarly, in a “double gate” third transistor, the active layer of the third transistor T3 crosses over a respective first gate line of the plurality of first gate lines GL1 twice (alternatively, the respective gate line crosses over the active layer of the third transistor T3 twice). Similarly, in a “double gate” seventh transistor, the active layer of the seventh transistor T7 crosses over the gate electrode of the seventh transistor 17 twice (alternatively, the gate electrode of the seventh transistor T7 crosses over the active layer of the seventh transistor T7 twice).

The pixel driving circuit further include a first node N1, a second node N2, a third node N3, and a fourth node N4. The first node N1 is connected to the gate electrode of the driving transistor Td, the first capacitor electrode Ce1, and the first electrode of the third transistor T3. The second node N2 is connected to the second electrode of the fourth transistor T4, the second electrode of the second transistor T2, and the first electrode of the driving transistor Td. The third node N3 is connected to the second electrode of the driving transistor Td, the second electrode of the third transistor T3, and the first electrode of the fifth transistor T5. The fourth node N4 is connected to the second electrode of the fifth transistor T5, the second electrode of the sixth transistor T6 and the anode of the light emitting element LE.

FIG. 2E is a timing diagram illustrating the operation of a pixel driving circuit in some embodiments according to the present disclosure. Referring to FIG. 2A to FIG. 2E, during one frame of image, the operation of the pixel driving circuit includes a reset sub-phase t1, a data write sub-phase t2, and a light emitting sub-phase 13. In the initial sub-phase 10), a turning-off reset control signal is provided through the respective reset control signal line of the plurality of reset control signal lines rst to the gate electrode of the first transistor T1 to turn off the first transistor T1. In the initial sub-phase t0, the respective first gate line of the plurality of first gate lines GL1 is provided with a turning-off signal, thus the second transistor T2 and the sixth transistor T6 are turned off. In the initial sub-phase t0, the respective second gate line of the plurality of second gate lines GL2 is provided with a turning-off signal, thus the third transistor T3 is turned off.

In the reset sub-phase t1, a turning-on reset control signal is provided through the respective reset control signal line of the plurality of reset control signal lines rst to the gate electrode of the first transistor T1 to turn on the first transistor T1; allowing an initialization voltage signal from the respective first reset signal line of the plurality of first reset signal lines Vint1 to pass from a first electrode of the first transistor T1 to a second electrode of the first transistor T1, and in turn to the first capacitor electrode Ce1 and the gate electrode of the driving transistor Td. The gate electrode of the driving transistor Td is initialized. The second capacitor electrode Ce2 receives a high voltage signal from the respective first voltage supply line of the plurality of first voltage supply lines Vdd. The first capacitor electrode Ce1 is charged in the reset sub-phase t1 due to an increasing voltage difference between the first capacitor electrode Ce1 and the second capacitor electrode Ce2. In the reset sub-phase t1, the respective first gate line of the plurality of first gate lines GL1 and the respective second gate line of a plurality of second gate lines GL2 are provided with a turning-off signal, thus the second transistor T2 and the third transistor T3 and the sixth transistor T6 are turned off. The respective light emitting control signal line of the plurality of light emitting control signal lines em is provided with a high voltage signal to turn off the fourth transistor T4 and the fifth transistor T5.

In the reset sub-phase t1, the first transistor T1 is turned on, an initialization voltage signal from the respective first reset signal line of the plurality of first reset signal lines Vint1 to pass from a first electrode of the first transistor T1 to a second electrode of the first transistor T1, and in turn to the gate electrode of the seventh transistor T7. In some embodiments, the initialization voltage signal from the respective first reset signal line has a voltage level in a range of −2V to −5V. In one example, the initialization voltage signal having the voltage level in the range of −2V to −5V is sufficient to turn on the seventh transistor T7.

In the data write sub-phase t2, the turning-off reset control signal is again provided through the respective reset control signal line of the plurality of reset control signal lines rst to the gate electrode of the first transistor T1 to turn off the first transistor T1. The respective first gate line of the plurality of first gate lines GL1 is provided with a turning-on signal, thus the second transistor T2 and the sixth transistor T6 are turned on. The respective second gate line of the plurality of second gate lines GL2 is provided with a turning-on signal, thus the third transistor T3 is turned on. A second electrode of the driving transistor Td is connected with the second electrode of the third transistor T3. A gate electrode of the driving transistor Td is electrically connected with the first electrode of the third transistor T3. Because the third transistor T3 is turned on in the data write sub-phase t2, the gate electrode and the second electrode of the driving transistor Td are connected and short circuited, and only the PN junction between the gate electrode and a first electrode of the driving transistor Td is effective, thus rendering the driving transistor Td in a diode connecting mode. The second transistor T2 is turned on in the data write sub-phase t2. The data voltage signal transmitted through the respective data line of a plurality of data lines DL is received by a first electrode of the second transistor T2, and in turn transmitted to the first electrode of the driving transistor Td, which is connected to the second electrode of the second transistor T2. A node N2 connecting to the first electrode of the driving transistor Td has a voltage level of the data voltage signal. Because only the PN junction between the gate electrode and a first electrode of the driving transistor Td is effective, the voltage level at the node N1 in the data write sub-phase t2 increase gradually to (Vdata+Vth), wherein the Vdata is the voltage level of the data voltage signal, and the Vth is the voltage level of the threshold voltage Th of the PN junction. The storage capacitor Cst is discharged because the voltage difference between the first capacitor electrode Ce1 and the second capacitor electrode Ce2 is reduced to a relatively small value. The respective light emitting control signal line of the plurality of light emitting control signal lines em is provided with a high voltage signal to turn off the fourth transistor T4 and the fifth transistor T5.

In the data write sub-phase t2, a turning-on reset control signal is provided through the respective first gate line of the plurality of first gate lines GL1 to the gate electrode of the sixth transistor T6 to turn on the sixth transistor T6; allowing an initialization voltage signal from the respective second reset signal line of the plurality of second reset signal lines Vint2 to pass from a first electrode of the sixth transistor T6 to a second electrode of the sixth transistor T6; and in turn to the node N4. The anode of the light emitting element LE is initialized.

In the light emitting sub-phase 13, the turning-off reset control signal is again provided through the respective reset control signal line of the plurality of reset control signal lines rst to the gate electrode of the first transistor T1 to turn off the first transistor T1. The respective first gate line of the plurality of first gate lines GL1 and the respective second gate line of a plurality of second gate lines GL2 are provided with a turning-off signal, the second transistor T2 and the third transistor T3 and the sixth transistor T6 are turned off. The respective light emitting control signal line of the plurality of light emitting control signal lines em is provided with a low voltage signal to turn on the fourth transistor T4 and the fifth transistor T5. The voltage level at the node N1 in the light emitting sub-phase t3 is maintained at (Vdata+Vth), the driving transistor Td is turned on by the voltage level, and working in the saturation area. A path is formed through the fourth transistor T4, the driving transistor Td, the fifth transistor T5, to the light emitting element LE. The driving transistor Td generates a driving current for driving the light emitting element LE to emit light. A voltage level at a node N3 connected to the second electrode of the driving transistor Td equals to a light emitting voltage of the light emitting element LE.

The array substrate in some embodiments includes a plurality of subpixels. In some embodiments, the plurality of subpixels includes a respective first subpixel, a respective second subpixel, a respective third subpixel, and a respective fourth subpixel. Optionally, a respective pixel of the array substrate includes the respective first subpixel, the respective second subpixel, the respective third subpixel, and the respective fourth subpixel. The plurality of subpixels in the array substrate are arranged in an array. In one example, the array of the plurality of subpixels includes a S1-S2-S3-S4 format repeating array, in which S1 stands for the respective first subpixel, S2 stands for the respective second subpixel, S3 stands for the respective third subpixel, and S4 stands for the respective fourth subpixel. In another example, the S1-S2-S3-S4 format is a C1-C2-C3-C4 format, in which C1 stands for the respective first subpixel of a first color, C2 stands for the respective second subpixel of a second color, C3 stands for the respective third subpixel of a third color, and C4 stands for the respective fourth subpixel of a fourth color. In another example, the S1-S2-S3-S4 format is a C1-C2-C3-C2′ format, in which C1 stands for the respective first subpixel of a first color, C2 stands for the respective second subpixel of a second color, C3 stands for the respective third subpixel of a third color, and C2′ stands for the respective fourth subpixel of the second color. In another example, the C1-C2-C3-C2′ format is a R-G-B-G format, in which the respective first subpixel is a red subpixel, the respective second subpixel is a green subpixel, the respective third subpixel is a blue subpixel, and the respective fourth subpixel is a green subpixel.

In some embodiments, a minimum repeating unit of the plurality of subpixels of the array substrate includes the respective first subpixel, the respective second subpixel, the respective third subpixel, and the respective fourth subpixel. Optionally, each of the respective first subpixel, the respective second subpixel, the respective third subpixel, and the respective fourth subpixel, includes the first transistor T1, the second transistor T2, the third transistor T3, the fourth transistor T4, the fifth transistor T5, the sixth transistor T6, and the driving transistor Td. Optionally, each of the respective first subpixel, the respective second subpixel, the respective third subpixel, and the respective fourth subpixel, includes the first transistor T1, the second transistor T2, the third transistor T3, the fourth transistor T4, the fifth transistor T5, the sixth transistor T6, the seventh transistor T7, and the driving transistor Td.

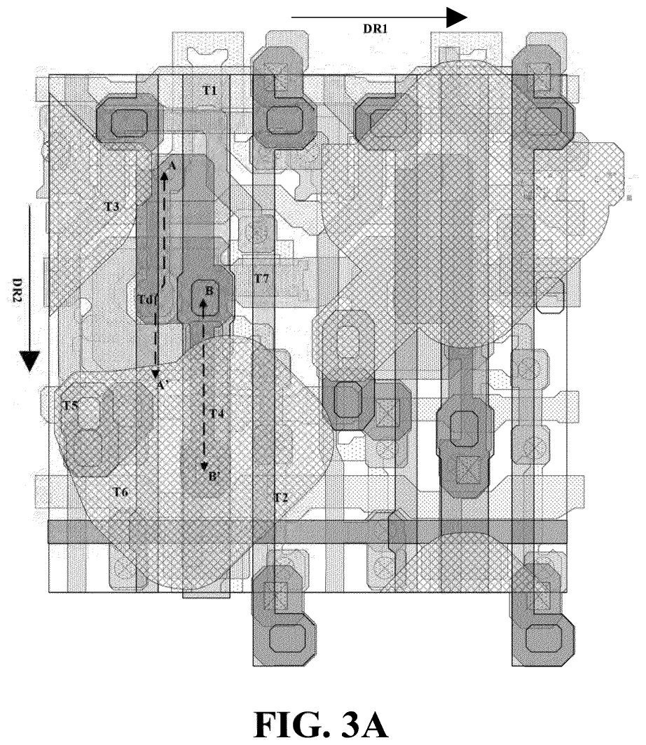

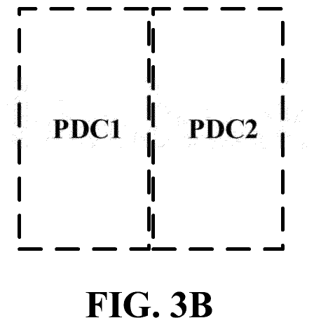

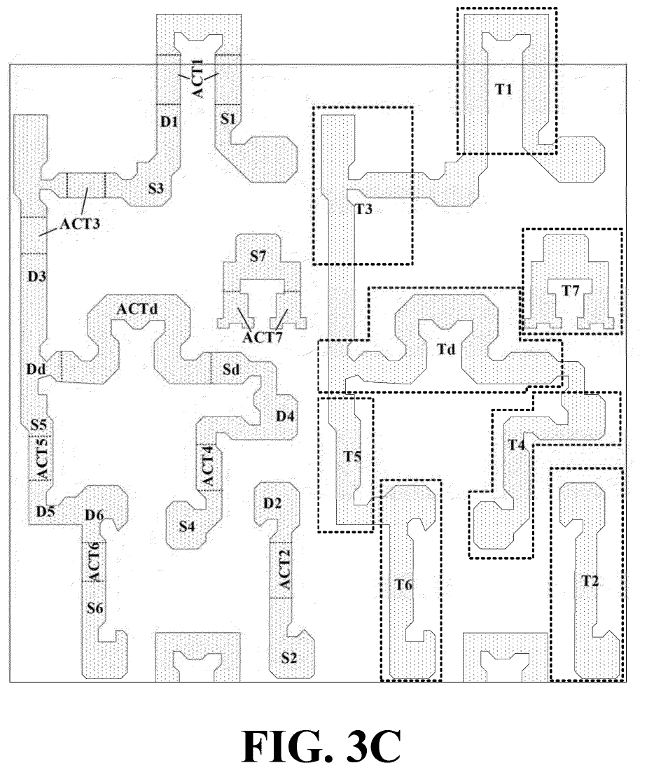

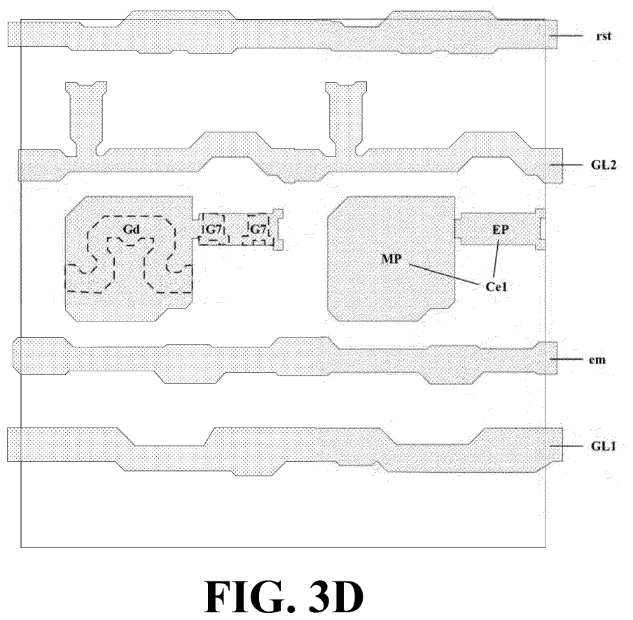

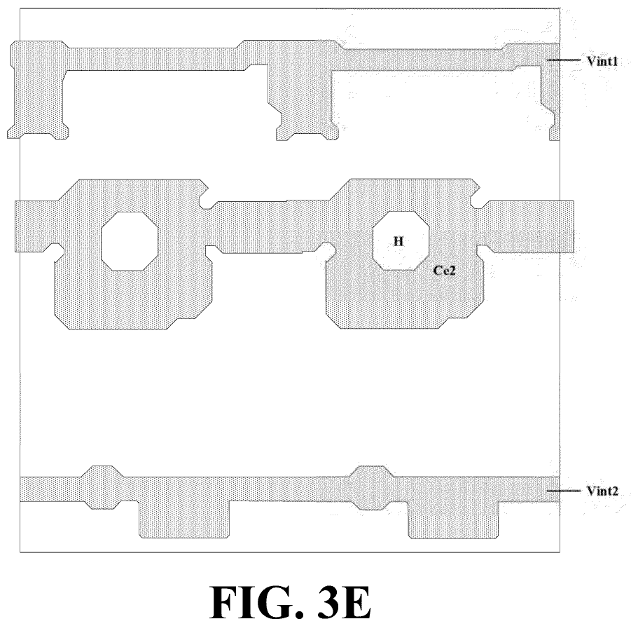

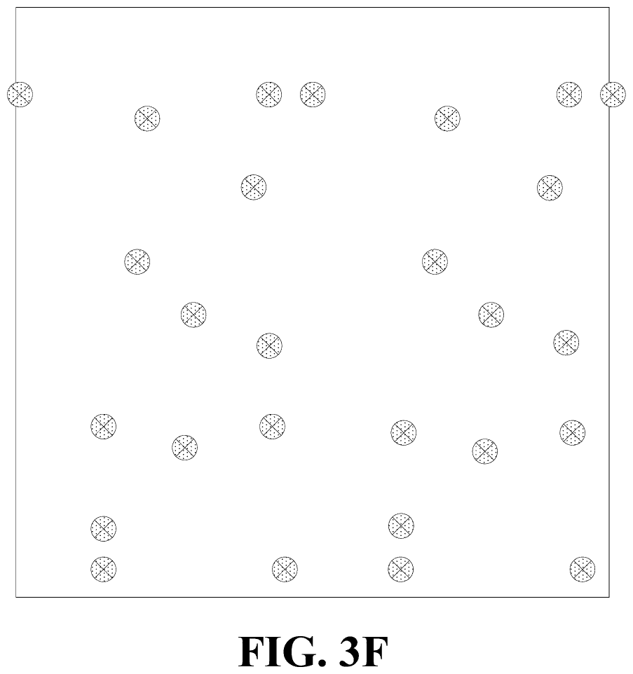

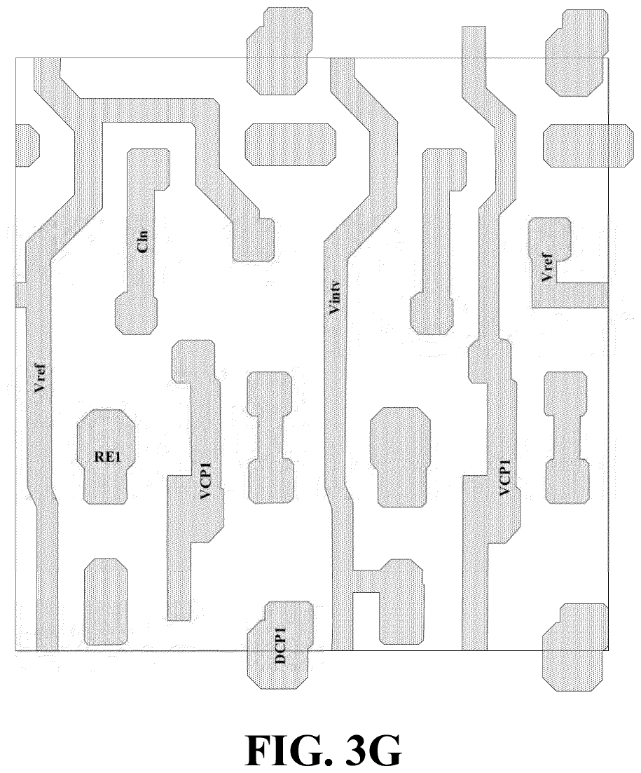

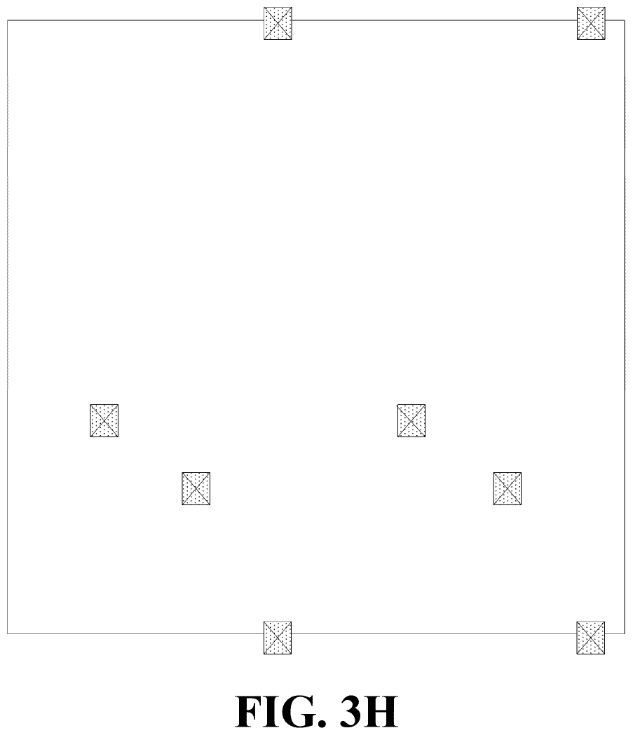

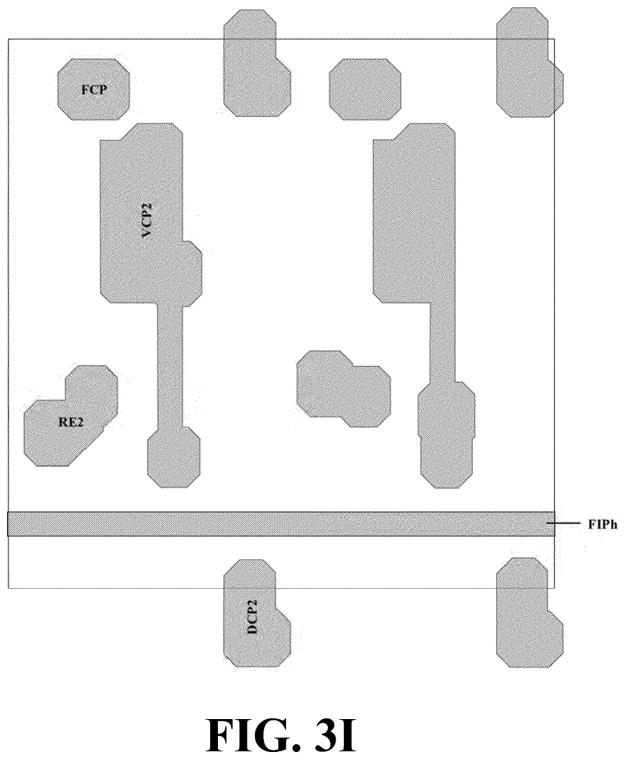

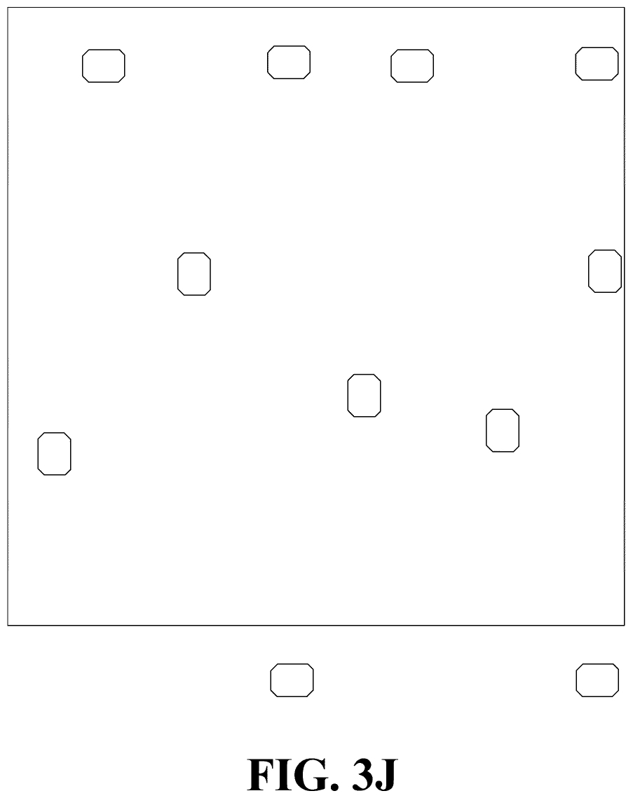

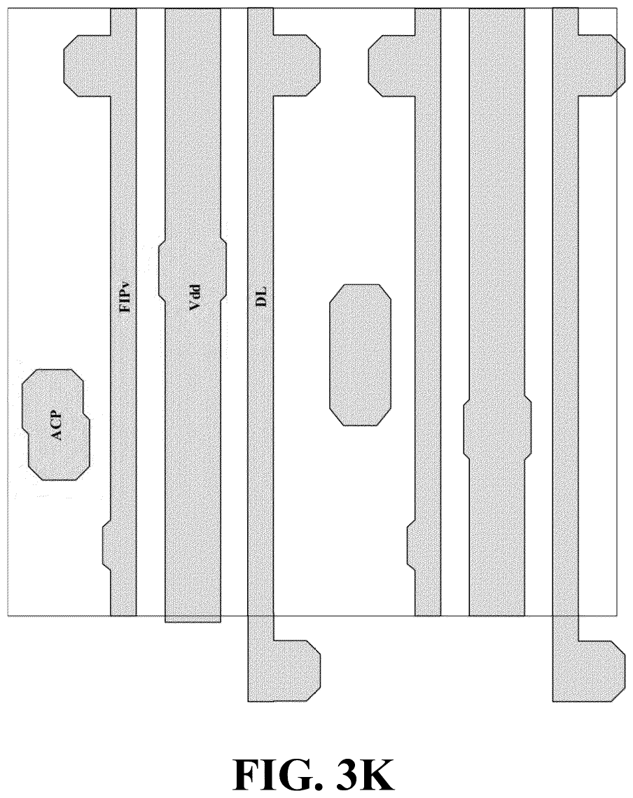

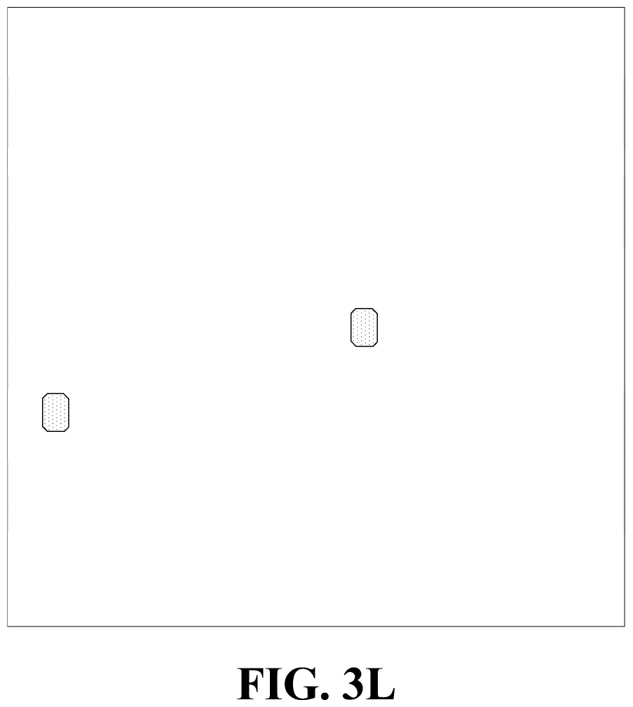

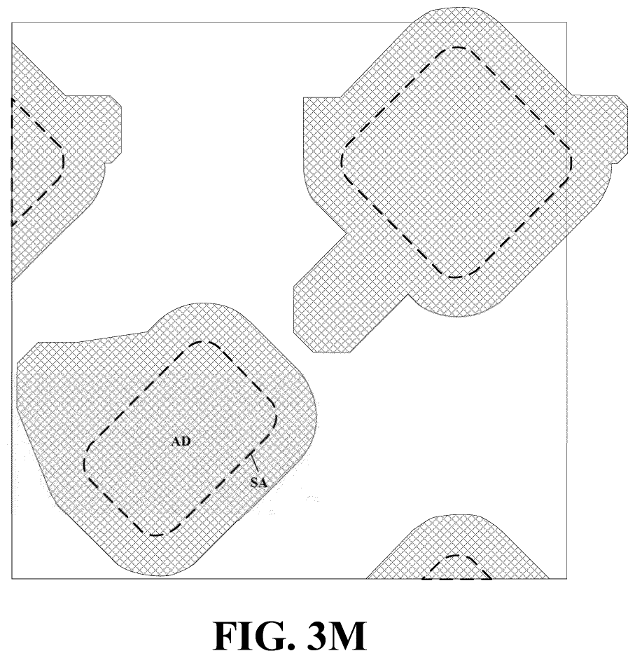

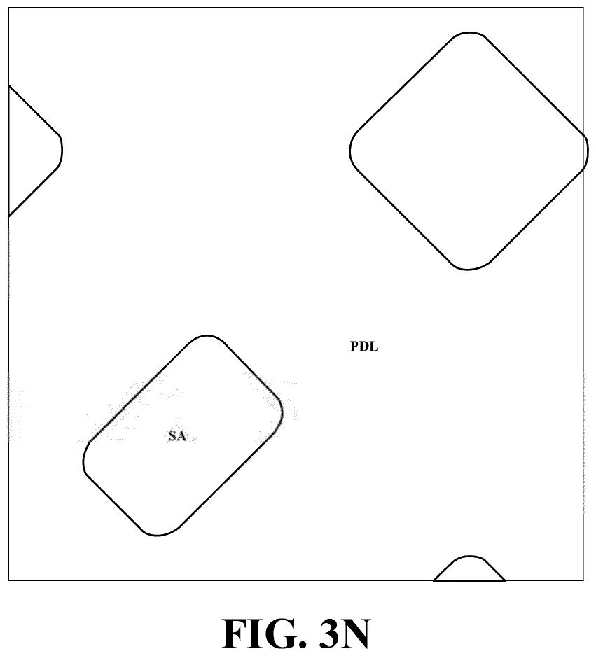

FIG. 3A is a diagram illustrating the structure of an array substrate in some embodiments according to the present disclosure. FIG. 3B is a schematic diagram illustrating an arrangement of a plurality of pixel driving circuits in an array substrate depicted in FIG. 3A. FIG. 3A and FIG. 3B depicts a portion of the array substrate having two pixel driving circuits, including PDC1 and PDC2.

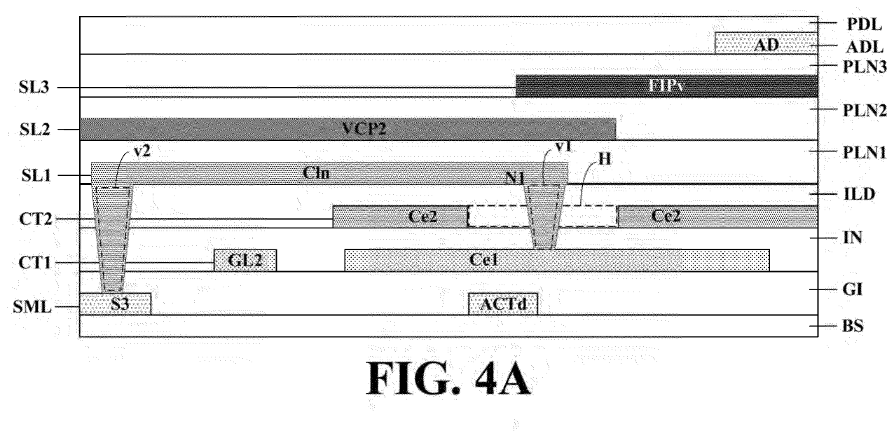

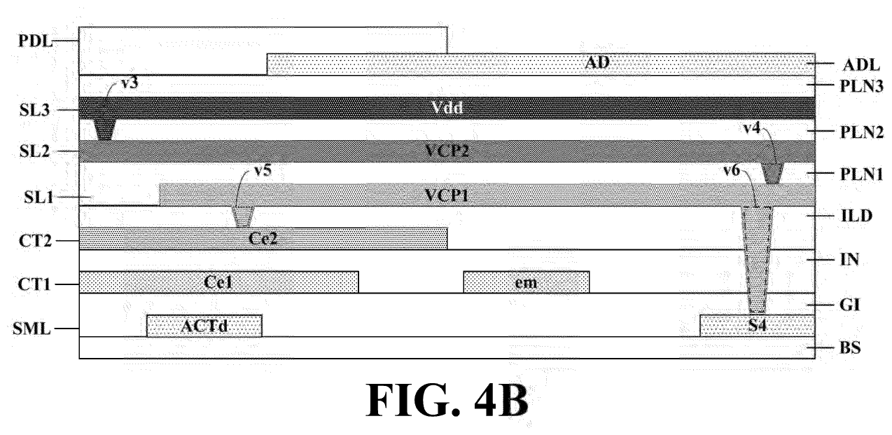

FIG. 3C is a diagram illustrating the structure of a semiconductor material layer in an array substrate depicted in FIG. 3A. FIG. 3D is a diagram illustrating the structure of a first conductive layer in an array substrate depicted in FIG. 3A. FIG. 3E is a diagram illustrating the structure of a second conductive layer in an array substrate depicted in FIG. 3A. FIG. 3F is a diagram illustrating the structure of an inter-layer dielectric layer in an army substrate depicted in FIG. 3A. FIG. 3G is a diagram illustrating the structure of a first signal line layer in an array substrate depicted in FIG. 3A. FIG. 3H is a diagram illustrating the structure of a first planarization layer in an array substrate depicted in FIG. 3A. FIG. 3I is a diagram illustrating the structure of a second signal line layer in an array substrate depicted in FIG. 3A. FIG. 3J is a diagram illustrating the structure of a second planarization layer in an array substrate depicted in FIG. 3A. FIG. 3K is a diagram illustrating the structure of a third signal line layer in an array substrate depicted in FIG. 3A. FIG. 3L is a diagram illustrating the structure of a third planarization layer in an array substrate depicted in FIG. 3A. FIG. 3M is a diagram illustrating the structure of an anode layer in an array substrate depicted in FIG. 3A. FIG. 3N is a diagram illustrating the structure of a pixel definition layer in an array substrate depicted in FIG. 3A. FIG. 4A is a cross-sectional view along an A-A′ line in FIG. 3A. FIG. 4B is a cross-sectional view along a B-B′ line in FIG. 3A.

Referring to FIG. 3A to FIG. 3M, and FIG. 4A to FIG. 4C, in some embodiments, the display panel includes a base substrate BS, a semiconductor material layer SML on the base substrate BS, a gate insulating layer GI on a side of the semiconductor material layer SML away from the base substrate BS, a first conductive layer CT1 on a side of the gate insulating layer GI away from the semiconductor material layer SML, an insulating layer IN on a side of the first conductive layer CT1 away from the gate insulating layer GI, a second conductive layer CT2 on a side of the insulating layer IN away from the first conductive layer CT1, an inter-layer dielectric layer ILD on a side of the second conductive layer CT2 away from the insulating layer IN, a first signal line layer SL1 on a side of the inter-layer dielectric layer ILD away from the second conductive layer CT2, a first planarization layer PLN1 on a side of the first signal line layer SL1 away from the inter-layer dielectric layer ILD, a second signal line layer SL2 on a side of the first planarization layer PLN1 away from the first signal line layer SL1, a second planarization layer PLN2 on a side of the second signal line layer SL2 away from the first planarization layer PLN1, a third signal line layer SL3 on a side of the second planarization layer PLN2 away from the second signal line layer SL2, a third planarization layer PLN3 on a side of the third signal line layer SL3 away from the second planarization layer PLN2, an anode layer ADL on a side of the third planarization layer PLN3 away from the third signal line layer SL3, and a pixel definition layer PDL on a side of the anode layer ADL away from the base substrate BS.

Referring to FIG. 2D, FIG. 3A, and FIG. 3C, a respective pixel driving circuit is annotated with labels indicating regions corresponding to the plurality of transistors in the respective pixel driving circuit, including the first transistor T1, the second transistor T2, the third transistor T3, the fourth transistor T4, the fifth transistor T5, the sixth transistor T6, the seventh transistor T7, and the driving transistor Td. The respective pixel driving circuit is further annotated with labels indicating components of each of the plurality of transistors in the pixel driving circuit. For example, the first transistor T1 includes an active layer ACT1, a first electrode S1, and a second electrode D1. The second transistor T2 includes an active layer ACT2, a first electrode S2, and a second electrode D2. The third transistor T3 includes an active layer ACT3, a first electrode S3, and a second electrode D3. The fourth transistor T4 includes an active layer ACT4, a first electrode S4, and a second electrode D4. The fifth transistor T5 includes an active layer ACT5, a first electrode S5, and a second electrode D5. The sixth transistor T6 includes an active layer ACT6, a first electrode S6, and a second electrode D6. The seventh transistor T7 includes an active layer ACT7, a first electrode S7, and a second electrode D7. The driving transistor Td includes an active layer ACTd, a first electrode Sd, and a second electrode Dd. In one example, the active layers (ACT1, ACT3, ACT4, ACT5, ACT6, and ACTd) of the transistors (T1, T3, T4. T5, T6, and Td) in the respective pixel driving circuit are parts of a unitary structure. In another example, the active layers (ACT1, ACT3, ACT4. ACT5, ACT6, and ACTd), the first electrodes (S1, S3, S4, S5, S6, and Sd), and the second electrodes (D1, D3, D4, D5, D6, and Dd) of the transistors (T1, T3, T4, T5, T6, and Td) in the respective pixel driving circuit are parts of a unitary structure. In another example, the active layers (ACT1, ACT2, ACT3, ACT4, ACT5, ACT6, ACT7, and ACTd) of the transistors (T1, T2, T3, T4, T5, T6, T7, and Td) are in a same layer. In another example, the active layers (ACT1, ACT2, ACT3, ACT4, ACT5, ACT6, ACT7, and ACTd), the first electrodes (S1, S2, S3, S4, S5, S6, S7, and Sd), and the second electrodes (D1, D2, D3, D4, D5, D6, D7, and Dd) of the transistors (T1, T2, T3, T4, T5, T6, 7, and Td) are in a same layer.

As used herein, the active layer refers to a component of the transistor comprising at least a portion of the semiconductor material layer whose orthographic projection on the base substrate overlaps with an orthographic projection of a gate electrode on the base substrate. A first electrode refers to a component of the transistor connected to one side of the active layer, and a second electrode refers to a component of the transistor connected to another side of the active layer. In the context of a double-gate type transistor (for example, the third transistor T3), the active layer refers to a component of the transistor comprising a first portion of the semiconductor material layer whose orthographic projection on the base substrate overlaps with an orthographic projection of a first gate on the base substrate, a second portion of the semiconductor material layer whose orthographic projection on the base substrate overlaps with an orthographic projection of a second gate on the base substrate, and a third portion between the first portion and the second portion. In the context of a double-gate type transistor, a first electrode refers to a component of the transistor connected to a side of the first portion distal to the third portion, and a second electrode refers to a component of the transistor connected to a side of the second portion distal to the third portion.

Referring to FIG. 2D, FIG. 3A, and FIG. 3D, the first conductive layer in some embodiments includes a plurality of first gate lines GL1, a plurality of second gate lines GL2, a plurality of reset control signal lines rst, a plurality of light emitting control signal lines em, and a first capacitor electrode Ce1 of the storage capacitor Cst. Optionally, at least a portion of the first capacitor electrode Ce1 is the gate electrode (denoted as G7) of the seventh transistor T7, and at least another portion of the first capacitor electrode Ce1 is the gate electrode (denoted as Gd) of the driving transistor Td. In some embodiments, the first capacitor electrode Ce1 includes a main part MP and an extension part EP connected to each other. The extension part EP extends away from the main part MP of the first capacitor electrode Ce1. Optionally, the extension part EP extends away from the main part MP of the first capacitor electrode Ce1 along the first direction DR1. Optionally, the main part MP includes the gate electrode Gd of the driving transistor Td. Optionally, the extension part EP includes the gate electrode G7 of the seventh transistor T7. Various appropriate electrode materials and various appropriate fabricating methods may be used to make the first conductive layer. For example, a conductive material may be deposited on the substrate by a plasma-enhanced chemical vapor deposition (PECVD) process and patterned. Examples of appropriate conductive materials for making the first conductive layer include, but are not limited to, aluminum, copper, molybdenam, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of first gate lines GL1, the plurality of second gate lines GL2, the plurality of reset control signal lines rst, the plurality of light emitting control signal lines em, and the first capacitor electrode Ce1 of the storage capacitor Cst are in a same layer.

As used herein, the term “same layer” refers to the relationship between the layers simultaneously formed in the same step. In one example, the plurality of first gate lines GL1 and the first capacitor electrode Ce1 are in a same layer when they are formed as a result of one or more steps of a same patterning process performed in a same layer of material. In another example, the plurality of first gate lines GL1 and the first capacitor electrode Ce1 can be formed in a same layer by simultaneously performing the step of forming the plurality of first gate lines GL1, and the step of forming the first capacitor electrode Ce1. The term “same layer” does not always mean that the thickness of the layer or the height of the layer in a cross-sectional view is the same.

Referring to FIG. 2D, FIG. 3A, and FIG. 3E, the second conductive layer in some embodiments includes a plurality of first reset signal lines Vint1, a plurality of second reset signal lines Vint2, and a second capacitor electrode Ce2 of the storage capacitor Cst. Various appropriate conductive materials and various appropriate fabricating methods may be used to make the second conductive layer. For example, a conductive material may be deposited on the substrate by a plasma-enhanced chemical vapor deposition (PECVD) process and patterned. Examples of appropriate conductive materials for making the second conductive layer include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the plurality of first reset signal lines Vint1, the plurality of second reset signal lines Vint2, and the second capacitor electrode Ce2 of the storage capacitor Cst are in a same layer.

Vias extending through the inter-layer dielectric layer ILD are depicted in FIG. 3F.

Referring to FIG. 2D. FIG. 3A, and FIG. 3G, the first signal line layer in some embodiments includes a node connecting line Cin, a first voltage signal connecting pad VCP1, a first data signal connecting pad DCP1, a first relay electrode RE1, a reference signal line Vref, and a plurality of third reset signal lines Vintv. The plurality of third reset signal lines Vintv are interconnected with the plurality of second reset signal lines Vint2, forming an interconnected reset signal network. The first data signal connecting pad DCP1 and a second data signal connecting pad in the second signal layer are configured to connect a respective data line of the plurality of data lines to a first electrode of the second transistor T2. The first voltage signal connecting pad VCP1 and a second voltage signal connecting pad VCP2 in the second signal layer are configured to connect a respective first voltage supply line of the plurality of first voltage supply lines with a first electrode of the fourth transistor T4, and connect the respective first voltage supply line of the plurality of first voltage supply lines with the second capacitor electrode Ce2 of the storage capacitor Cst. The node connecting line Cln connects the first capacitor electrode Ce1 and the first electrode of the third transistor T3 in a respective pixel driving circuit together. Optionally, the plurality of third reset signal lines Vintv extend along a direction substantially parallel to a second direction DR2; the plurality of first reset signal lines Vint1 and the plurality of second reset signal lines Vint2 extend along a direction substantially parallel to a first direction DR1. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees. 0 degree to approximately 25 degrees, 0 degree to approximately 30 degrees.

Various appropriate conductive materials and various appropriate fabricating methods may be used to make the first signal line layer. For example, a conductive material may be deposited on the substrate by a plasma-enhanced chemical vapor deposition (PECVD) process and patterned. Examples of appropriate conductive materials for making the first signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the first signal line layer includes a plurality of sub-layers stacked together. In one example, the first signal line layer includes a stacked titanium/aluminum/titanium multi-layer structure. In another example, the first signal line layer includes a stacked molybdenum/aluminum/molybdenum multi-layer structure. Optionally, the node connecting line Cln, the first voltage signal connecting pad VCP1, the first data signal connecting pad DCP1, the first relay electrode RE1, the reference signal line Vref, and the plurality of third reset signal lines Vintv are in a same layer.

Vias extending through the first planarization layer PLN1 are depicted in FIG. 3H.

Referring to FIG. 2D, FIG. 3A, and FIG. 3I, the second signal line layer in some embodiments includes a plurality of first fanout connecting lines FIPh, a second relay electrode RE2, a second voltage signal connecting pad VCP2, a second data signal connecting pad DCP2, and a fanout connecting pad FCP. The first data signal connecting pad and a second data signal connecting pad DCP2 in the second signal layer are configured to connect a respective data line of the plurality of data lines to a first electrode of the second transistor T2. The first voltage signal connecting pad and a second voltage signal connecting pad VCP2 in the second signal layer are configured to connect a respective first voltage supply line of the plurality of first voltage supply lines with a first electrode of the fourth transistor T4, and connect the respective first voltage supply line of the plurality of first voltage supply lines with the second capacitor electrode Ce2 of the storage capacitor Cst. The first relay electrode and the second relay electrode RE2 connect the fourth node N4 and an anode connecting pad together. The first relay electrode is connected to second electrodes of the fifth transistor T5 and the sixth transistor T6. The anode connecting pad is in the third signal line layer, and is connected to an anode in a respective subpixel.

Various appropriate conductive materials and various appropriate fabricating methods may be used to make the second signal line layer. For example, a conductive material may be deposited on the substrate by a plasma-enhanced chemical vapor deposition (PECVD) process and patterned. Examples of appropriate conductive materials for making the second signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the second signal line layer includes a plurality of sub-layers stacked together. In one example, the second signal line layer includes a stacked titanium/aluminum/titanium multi-layer structure. In another example, the second signal line layer includes a stacked molybdenum/aluminum/molybdenum multi-layer structure. Optionally, the plurality of first fanout connecting lines FIPh, the second relay electrode RE2, the second voltage signal connecting pad VCP2, the second data signal connecting pad DCP2, and the fanout connecting pad FCP are in a same layer.

Vias extending through the second planarization layer PLN2 are depicted in FIG. 3J.

Referring to FIG. 2D, FIG. 3A, and FIG. 3K, the third signal line layer in some embodiments includes a plurality of data line DL, a plurality of first voltage supply lines Vdd, a plurality of second fanout connecting lines FIPv, and an anode connecting pad ACP. The anode connecting pad ACP is electrically connected to second electrodes of the fifth transistor T5 and the sixth transistor T6 in the respective pixel driving circuit through a first relay electrode and a second relay electrode. The anode connecting pad ACP is electrically connected to an anode in a respective subpixel. A respective first voltage supply line of the plurality of first voltage supply lines Vdd is electrically connected to the second capacitor electrode Ce2 of the storage capacitor Cst through the second voltage signal connecting pad VCP2 and the first voltage signal connecting pad VCP1, and is electrically connected to the first electrode of the fourth transistor T4 through the second voltage signal connecting pad VCP2 and the first voltage signal connecting pad VCP1. A respective data line of the plurality of data lines DL is electrically connected to the first electrode of the second transistor T2 through the second data signal connecting pad DCP2 and the first signal connecting pad DCP1.

Various appropriate conductive materials and various appropriate fabricating methods may be used to make the third signal line layer. For example, a conductive material may be deposited on the substrate by a plasma-enhanced chemical vapor deposition (PECVD) process and patterned. Examples of appropriate conductive materials for making the third signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the third signal line layer includes a plurality of sub-layers stacked together. In one example, the third signal line layer includes a stacked titanium/aluminum/titanium multi-layer structure. In another example, the third signal line layer includes a stacked molybdenum/aluminum/molybdenum multi-layer structure. Optionally, the plurality of data line DL, the plurality of first voltage supply lines Vdd, the plurality of second fanout connecting lines FIPv, and the anode connecting pad ACP are in a same layer.

Vias extending through the third planarization layer PLN3 are depicted in FIG. 3L.

Referring to FIG. 2D, FIG. 3A, and FIG. 3M, the array substrate further includes an anode layer ADL. A plurality of subpixel apertures SA respectively corresponding to a plurality of anodes are denoted in FIG. 3M. Vias extending through the third planarization layer PLN3 are depicted in FIG. 3L. A respective anode is connected to a respective anode connecting pad through a respective via extending through the third planarization layer PLN3.

Referring to FIG. 2D, FIG. 3A, and FIG. 3N, the array substrate further includes a pixel definition layer PDL defining a plurality of subpixel apertures SA.

Referring to FIG. 2D, FIG. 3A, FIG. 3D, FIG. 3E, and FIG. 4A, in some embodiments, an orthographic projection of the second capacitor electrode Ce2 on a base substrate BS completely covers, with a margin, an orthographic projection of the first capacitor electrode Ce1 on the base substrate BS except for a hole region H in which a portion of the second capacitor electrode Ce2 is absent. In some embodiments, the first signal line layer includes a node connecting line Cln on a side of the inter-layer dielectric layer ILD away from the second capacitor electrode Ce2. The node connecting line Cln is in a same layer as the first voltage signal connecting pad VCP1, the first data signal connecting pad DCP1, the reference signal line Vref, and the plurality of third reset signal lines Vintv.

In some embodiments, the second capacitor electrode Ce2 is on a side of the gate insulating layer IN away from the base substrate BS. Optionally, the array substrate further includes a first via v1 and a second via v2. The first via v1 is in the hole region H and extends through the inter-layer dielectric layer ILD and the insulating layer IN. The second via v2 extends through the inter-layer dielectric layer ILD, the insulating layer IN, and the gate insulating layer GI. Optionally, the node connecting line Cin is connected to the first capacitor electrode Ce1 through the first via v1, and the node connecting line Cin is connected the semiconductor material layer SML through the second via v2. Optionally, the node connecting line Cln is connected to the first electrode S3 of third transistor, as depicted in FIG. 4A.

Referring to FIG. 2D, FIG. 3A to FIG. 3N, and FIG. 4B, in some embodiments, the array substrate further includes a third via v3, a fourth via v4, a fifth via v5, and a sixth via v6. The third via v3 extends through the second planarization layer PLN2. The fourth via v4 extends through the first planarization layer PLN1. The fifth via v5 extends through the inter-layer dielectric layer ILD. The sixth via v6 extends through the inter-layer dielectric layer ILD, the insulating layer IN, and the gate insulating layer GI. A respective first voltage supply line of the plurality of first voltage supply lines Vdd is electrically connected to the second voltage signal connecting pad VCP2 through the third via v3. The second voltage signal connecting pad VCP2 is connected to the first voltage signal connecting pad VCP1 through the fourth via v4. The first voltage signal connecting pad VCP1 is connected to the second capacitor electrode Ce2 of the storage capacitor Cst through the fifth via v5. The first voltage signal connecting pad VCP1 is connected to the first electrode S4 of the fourth transistor T4 through the sixth via v6.

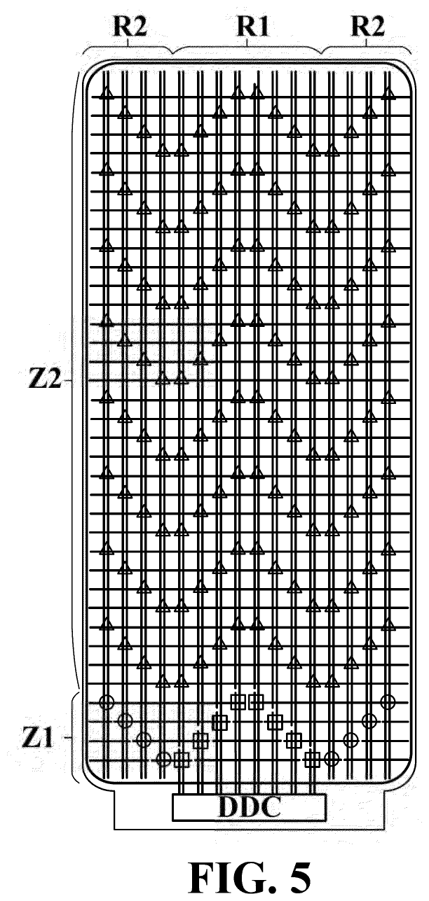

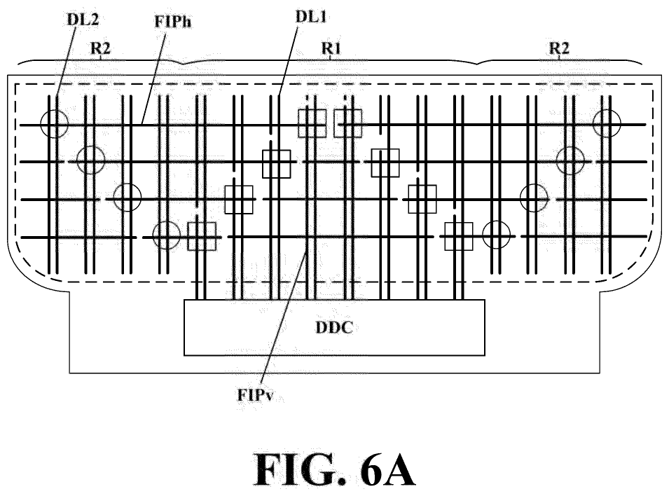

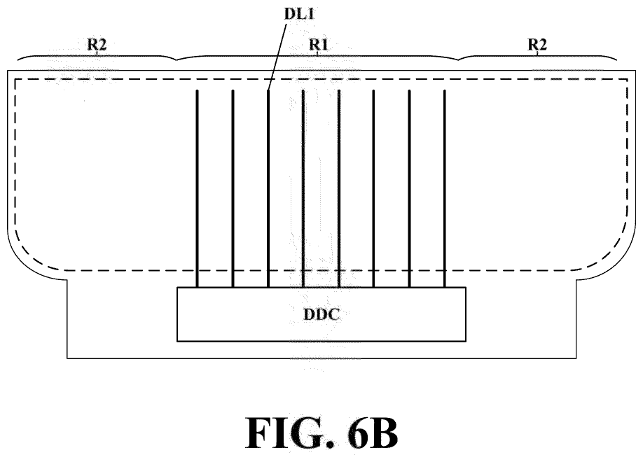

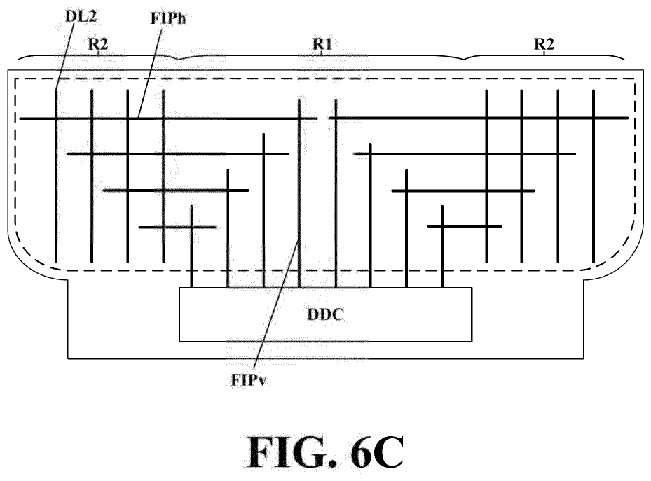

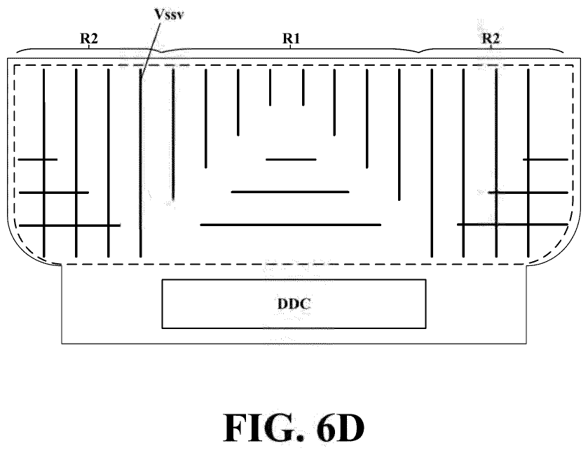

FIG. 5 illustrates a layout of signal lines in an array substrate in some embodiments according to the present disclosure. FIG. 6A illustrates a layout of signal lines in a portion of an array substrate in some embodiments according to the present disclosure. Referring to FIG. 5 and FIG. 6A, the array substrate in some embodiments includes a plurality of data lines, a plurality of first fanout connecting lines FIPh, and a plurality of second fanout connecting lines FIPv.

The array substrate includes a first region R1 and a second region R2 outside the first region R1. The first region R1 includes a plurality of first columns of subpixels, the second region R2 includes a plurality of second columns of subpixels. The plurality of first columns of subpixels are different from the plurality of second columns of subpixels. In some embodiments, the first region R1 and the second region R2 are in a display area of the array substrate. As used herein, the term “display area” refers to an area of an array substrate in a display panel where image is actually displayed. Optionally, the display area may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding to a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels.

FIG. 6B illustrates a layout of a plurality of first data lines in the portion of the array substrate depicted in FIG. 6A. FIG. 6C illustrates a layout of a plurality of second data lines, a plurality of first fanout connecting lines, and a plurality of second fanout connecting lines in the portion of the array substrate depicted in FIG. 6A. Referring to FIG. 5, FIG. 6A to FIG. 6C, the plurality of data lines includes a plurality of first data lines DL1 configured to provide data signals to the plurality of first columns of subpixels in the first region R1, and a plurality of second data lines DL2 configured to provide data signals to the plurality of second columns of subpixels in the second region R2.

In some embodiments, the plurality of first data lines DL1 are connected to the data driving circuit DDC; and the plurality of second data lines DL2 are connected to the data driving circuit DDC through the plurality of first fanout connecting lines FIPh and the plurality of second fanout connecting lines FIPv. Optionally, a respective second data line of the plurality of second data lines DL2 is connected to the data driving circuit DDC through a respective first fanout connecting line of the plurality of first fanout connecting lines FIPh and a respective second fanout connecting line of the plurality of second fanout connecting lines FIPv. The respective first fanout connecting line of the plurality of first fanout connecting lines FIPh and the respective second fanout connecting line of the plurality of second fanout connecting lines FIPv are connected to each other. The plurality of first fanout connecting lines FIPh and the plurality of second fanout connecting lines FIPv are substantially (e.g., at least 50%, at least 60%, at least 70%, at least 80%, at least 90%, at least 95%, at least 98%, at least 99%, or 100%) in the display area of the array substrate.

A circle mark in FIG. 5, FIG. 6A, and FIG. 6C denotes a connection between the respective first fanout connecting line of the plurality of first fanout connecting lines FIPh and the respective second data line of the plurality of second data lines DL2. A square mark in FIG. 5, FIG. 6A, and FIG. 6C denotes a connection between the respective first fanout connecting line of the plurality of first fanout connecting lines FIPh and the respective second fanout connecting line of the plurality of second fanout connecting lines FIPv. Optionally, the respective second data line of the plurality of second data lines DL2 is connected to the respective first fanout connecting line of the plurality of first fanout connecting lines FIPh through a via extending through the second planarization layer. Optionally, the respective second fanout connecting line of the plurality of second fanout connecting lines FIPv is connected to the respective first fanout connecting line of the plurality of first fanout connecting lines FIPh through a via extending through the second planarization layer.

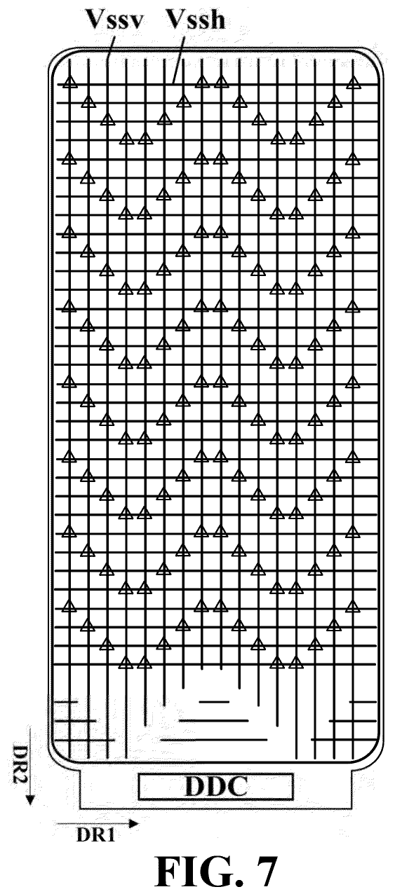

FIG. 6D illustrates a layout of signal lines not involved in data signal transmission in the portion of the array substrate depicted in FIG. 6A. FIG. 7 illustrates a layout of signal lines not involved in data signal transmission in the array substrate depicted in FIG. 5. Referring to FIG. 5, FIG. 6A, FIG. 6D, and FIG. 7, the array substrate in some embodiments further includes a plurality of second voltage supply lines Vssv and a plurality of third voltage supply lines Vssh. The plurality of second voltage supply lines Vssv extend along a direction substantially parallel to the second direction DR2. The plurality of third voltage supply lines Vssh extend along a direction substantially parallel to the first direction DR1.

In some embodiments, the plurality of first voltage supply lines are configured to provide a first reference voltage signal (e.g., a high reference voltage signal). The plurality of second voltage supply lines Vssv and the plurality of third voltage supply lines Vssh are configured to provide a second reference voltage signal (e.g., a low reference voltage signal). Optionally, the first reference voltage signal is a constant voltage signal, the second reference voltage signal is a constant voltage signal, the first reference voltage signal has a voltage level higher than a voltage level of the second reference voltage signal.

In some embodiments, the plurality of third voltage supply lines Vssh and the plurality of first fanout connecting lines FIPh are in a same layer; and the plurality of second voltage supply lines Vssv and the plurality of second fanout connecting lines FIPv are in a same layer. Optionally, the plurality of third voltage supply lines Vssh and the plurality of first fanout connecting lines FIPh are in the second signal line layer. Optionally, the plurality of second voltage supply lines Vssv and the plurality of second fanout connecting lines FIPv are in the third signal line layer.

In some embodiments, the plurality of second voltage supply lines Vssv and the plurality of third voltage supply lines Vssh form an interconnected voltage supply network. In some embodiments, a respective second voltage supply line of the plurality of second voltage supply lines Vssv is connected to one or more third voltage supply lines of the plurality of third voltage supply lines Vssh through one or more vias, e.g., one or more vias extending through the second planarization layer PLN2. The triangle mark in FIG. 5 and FIG. 7 denotes a connection between the respective second voltage supply line of the plurality of second voltage supply lines Vssv and the respective third voltage supply line of the plurality of third voltage supply lines Vssh.

In some embodiments, the array substrate includes a first zone Z1 and a second zone Z2 outside the first zone Z1. The first zone Z1 includes a plurality of first rows of subpixels, the second zone Z2 includes a plurality of second rows of subpixels. The plurality of first rows of subpixels are different from the plurality of second rows of subpixels. In some embodiments, the first zone Z1 and the second zone 22 are in a display area of the array substrate.

In some embodiments, connections between the plurality of first fanout connecting lines FIPh and the plurality of second data lines DL2 (circle marks) and connections between the plurality of first fanout connecting lines FIPh and the plurality of second fanout connecting lines FIPv (square marks) are in the first zone Z1. In some embodiments, connections between the plurality of second voltage supply lines Vssv and the plurality of third voltage supply lines Vssh (triangle marks) are in the second zone Z2.

In some embodiments, the connections between the plurality of first fanout connecting lines FIPh and the plurality of second data lines DL2 (circle marks) and connections between the plurality of first fanout connecting lines FIPh and the plurality of second fanout connecting lines FIPv (square marks) in the first zone Z1 constitute a first group of connections. In some embodiments, the connections between the plurality of second voltage supply lines Vssv and the plurality of third voltage supply lines Vssh in the second zone Z2 include one or more second groups of connections between the plurality of second voltage supply lines Vssv and the plurality of third voltage supply lines Vssh. In some embodiments, a respective second group of the one or more second groups of connections in the second zone Z2 has a same pattern as the first group of connections in the first zone Z1. In some embodiments, the first group of connections and the one or more second groups of connections are distributed substantially evenly in the array substrate, e.g., along the second direction DR2.

The inventors of the present disclosure discover that, by having the one or more second groups of connections having a same pattern as the first group of connections, and by having the first group of connections and the one or more second groups of connections distributed substantially evenly in the array substrate, an enhanced display uniformity can be achieved.

In some embodiments, the interconnected voltage supply network comprising the plurality of second voltage supply lines Vssv and the plurality of third voltage supply lines Vssh is electrically connected to a peripheral voltage supply line to receive a second reference voltage signal. Optionally, the interconnected voltage supply network is electrically connected to a cathode of the light emitting elements in the array substrate, and functions as an auxiliary cathode.

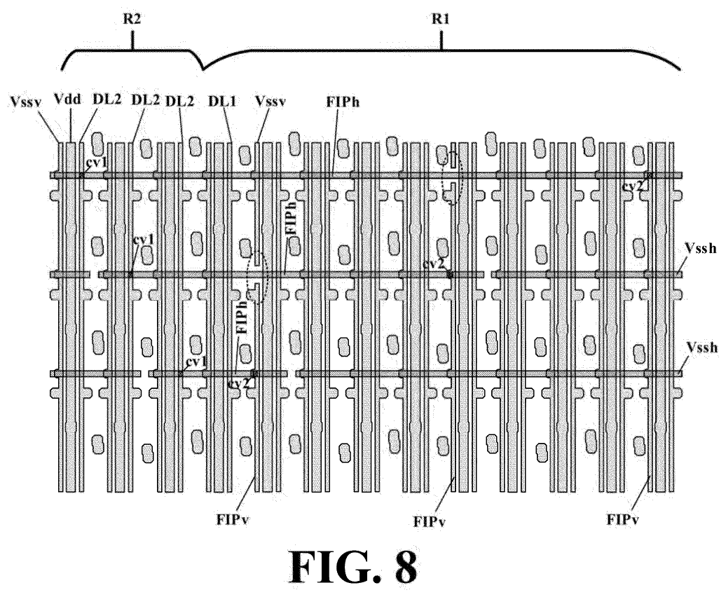

FIG. 8 illustrates a layout of signal lines in a second signal line layer and a third signal line layer in a portion of an array substrate in some embodiments according to the present disclosure. Referring to FIG. 8, a respective second data line of the plurality of second data lines DL2 is connected to a respective first fanout connecting line of the plurality of first fanout connecting lines FIPh through a first connecting via cy1 extending through the second planarization layer; and a respective second fanout connecting line of the plurality of second fanout connecting lines FIPv is connected to the respective first fanout connecting line of the plurality of first fanout connecting lines FIPh through a second connecting via cv2 extending through the second planarization layer.

In some embodiments, a respective second data line of the plurality of second data lines DL2 is configured to provide data signals to the plurality of second columns of subpixels in the second region R2. The respective second data line of the plurality of second data lines DL2 is connected to a respective first fanout connecting line of the plurality of first fanout connecting lines FIPh, the respective first fanout connecting line of the plurality of first fanout connecting lines FIPh is connected to a respective second fanout connecting line of the plurality of second fanout connecting lines FIPv. The respective second fanout connecting line of the plurality of second fanout connecting lines FIPv is in a first column of subpixels. The second column of subpixels is a different column from the first column of subpixels. In one example, the second column of subpixels is in the first region R1. In another example, the second column of subpixels is in the second region R2.

In some embodiments, in at least one column of subpixels, the array substrate includes an individual second voltage supply line of the plurality of second voltage supply lines Vssv and an individual second fanout connecting line of the plurality of second fanout connecting lines FIPv. The individual second voltage supply line of the plurality of second voltage supply lines Vssv and the individual second fanout connecting line of the plurality of second fanout connecting lines FIPv are disconnected from each other (as shown in the dotted line circle in FIG. 8).

In some embodiments, referring to FIG. 8, in at least one subpixel of the array substrate, an individual data line of the plurality of data lines (e.g., the plurality of first data lines DL1 or the plurality of second data lines DL2) and an individual second fanout connecting line of the plurality of second fanout connecting lines FIPv have a substantial mirror symmetry with respect to an individual first voltage supply line of the plurality of first voltage supply lines Vdd. Optionally, the individual data line of the plurality of data lines, the individual second fanout connecting line of the plurality of second fanout connecting lines FIPv, and the individual first voltage supply line of the plurality of first voltage supply lines Vdd extend along a direction substantially parallel to the second direction DR2.

In some embodiments, the plurality of data lines and the plurality of second fanout connecting lines FIPv are in a same layer. Optionally, the plurality of data lines and the plurality of second fanout connecting lines FIPv are in the third signal line layer.

In some embodiments, the plurality of data lines and the plurality of second fanout connecting lines FIPv are in a same layer as the plurality of first voltage supply lines Vdd. Optionally, the plurality of data lines, the plurality of second fanout connecting lines FIPv, and the plurality of first voltage supply lines Vdd are in the third signal line layer.

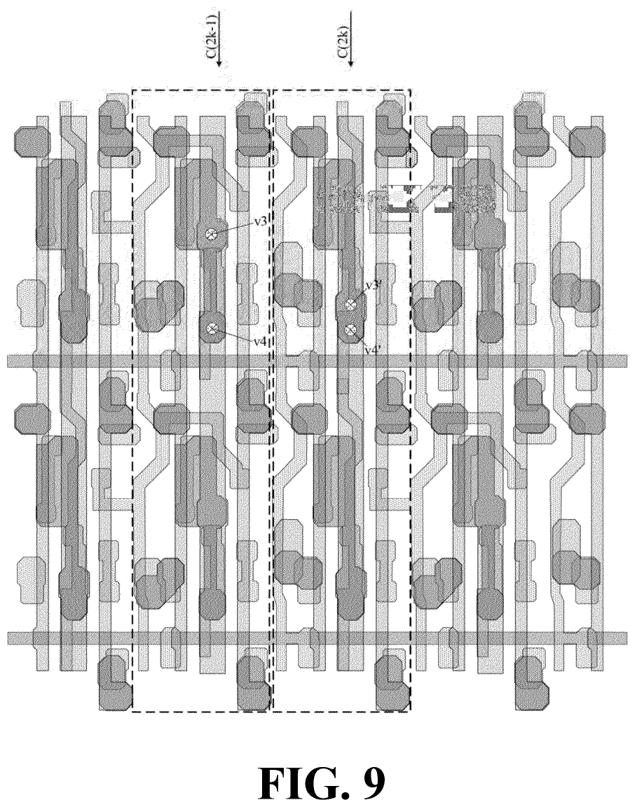

FIG. 9 illustrates a layout of signal lines in a first signal line layer, a second signal line layer, and a third signal line layer in a portion of an array substrate in some embodiments according to the present disclosure. Referring to FIG. 9, in some embodiments, subpixels in adjacent columns have different electrical environment underneath the third signal line layer. In some embodiments, referring to FIG. 9, FIG. 4A, FIG. 3A, FIG. 3G, and FIG. 3I, an orthographic projection of the second voltage signal connecting pad VCP2 on a base substrate BS at least partially overlaps with an orthographic projection the node connecting line Cln on the base substrate BS. Optionally, the orthographic projection of the second voltage signal connecting pad VCP2 on the substrate BS substantially covers (e.g., covers at least 80%, covers at least 85%, covers at least 90%, covers at least 95%, covers at least 99%, or completely covers) the orthographic projection the node connecting line Cln on the base substrate BS. The second voltage signal connecting pad VCP2 is configured to be provided with a constant voltage signal (e.g., a first reference voltage signal), shielding the node connecting line Cln from interference by signals transmitted in other signal lines.

Referring to FIG. 9, FIG. 3A, and FIG. 4B, in some embodiments, the array substrate further includes a third via v3 and a fourth via v4 in a first adjacent column of pixel driving circuits. In the first adjacent column of pixel driving circuits, a respective first voltage supply line of the plurality of first voltage supply lines Vdd is electrically connected to the second voltage signal connecting pad VCP2 through the third via v3. In the first adjacent column of pixel driving circuits, the second voltage signal connecting pad VCP2 is connected to the first voltage signal connecting pad VCP1 through the fourth via v4. In some embodiments, the array substrate further includes a third via v3′ and a fourth via v4′ in a second adjacent column of pixel driving circuits. In the second adjacent column of pixel driving circuits, a respective first voltage supply line of the plurality of first voltage supply lines Vdd is electrically connected to the second voltage signal connecting pad VCP2 through the third via v3′. In the second adjacent column of pixel driving circuits, the second voltage signal connecting pad VCP2 is connected to the first voltage signal connecting pad VCP1 through the fourth via v4″. In the first adjacent column of pixel driving circuits, the third via v3 and the fourth via v4 are spaced apart by a first distance. In the second adjacent column of pixel driving circuits, the third via v3′ and the fourth via v4′ are spaced apart by a second distance. The first distance is greater than the second distance, e.g., by at least 10%, by at least 20%, by at least 30%, by at least 40%, by at least 50%, by at least 60%, by at least 70%, by at least 80%, by at least 90%, by at least 100%, by at least 110%, by at least 120%, by at least 130%, by at least 140%, by at least 150%, by at least 160%, by at least 170%, by at least 180%, by at least 190%, or by at least 200%. By having the first distance greater than the second distance, an orthographic projection of the pixel definition layer PDL on a base substrate BS covers an orthographic projection of the third via v3 in the first adjacent column of pixel driving circuits on the base substrate BS, and covers an orthographic projection of the third via v3′ in the second adjacent column of pixel driving circuits on the base substrate BS. Optionally, an orthographic projection of the anode layer ADL on the base substrate BS is non-overlapping with the orthographic projection of the third via v3 in the first adjacent column of pixel driving circuits on the base substrate BS, and is non-overlapping with the orthographic projection of the third via v3′ in the second adjacent column of pixel driving circuits on the base substrate BS. By having the orthographic projection of the anode layer ADL on the base substrate BS non-overlapping with the orthographic projection of the third via v3 in the first adjacent column of pixel driving circuits on the base substrate BS, and non-overlapping with the orthographic projection of the third via v3′ in the second adjacent column of pixel driving circuits on the base substrate BS, the array substrate achieves an even surface of the planarization layer underneath the anodes. As a result, color shift issue can be alleviated.

Referring to FIG. 3A, FIG. 3E, and FIG. 3I, in some embodiments, an orthographic projection of a respective second reset signal line of the plurality of second reset signal lines Vint2 on a base substrate BS at least partially overlaps with an orthographic projection of a respective first fanout connecting line of the plurality of first fanout connecting lines FIPh on the base substrate BS. Optionally, the orthographic projection of the respective second reset signal line of the plurality of second reset signal lines Vint2 on the base substrate BS substantially covers (e.g., covers at least 80%, covers at least 85%, covers at least 90%, covers at least 95%, covers at least 99%, or completely covers) the orthographic projection the respective first fanout connecting line of the plurality of first fanout connecting lines FIPh on the base substrate BS. The respective second reset signal line of the plurality of second reset signal lines Vint2 is configured to be provided with a constant voltage signal, e.g., a reset signal. The inventors of the present disclosure discover that this unique structure is conductive to reducing interference from data signals transmitted in the plurality of first fanout connecting lines FIPh to other components in the array substrate.

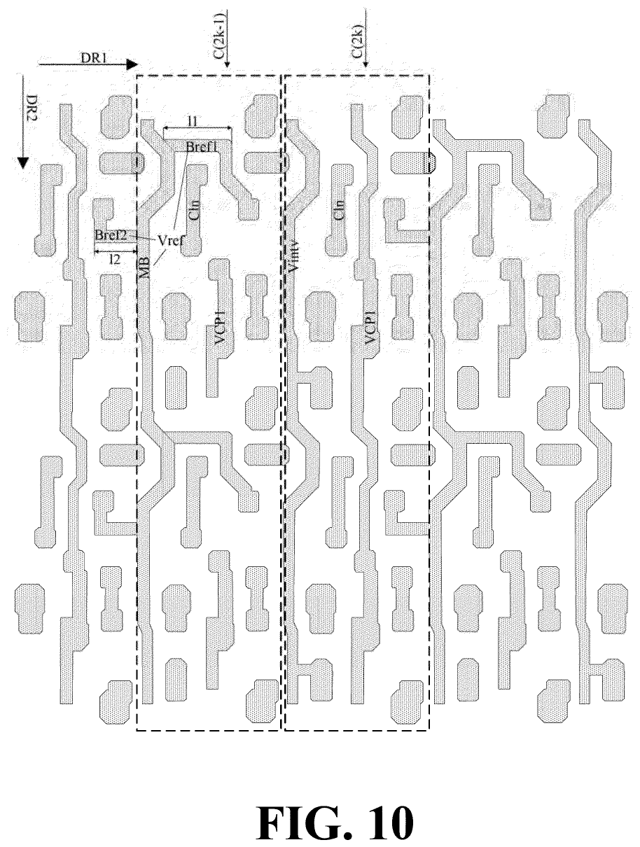

FIG. 10 illustrates a layout of signal lines in a first signal line layer in a portion of an array substrate in some embodiments according to the present disclosure. Referring to FIG. 10, in a first adjacent column of pixel driving circuits, the array substrate includes a respective reference signal line of the plurality of reference signal lines Vref. In a second adjacent column of pixel driving circuits, the array substrate includes a respective third reset signal line of the plurality of third reset signal lines Vintv. Optionally, the plurality of third reset signal lines Vintv are absent in the first adjacent column of pixel driving circuits.

In some embodiments, the plurality of pixel driving circuits are arranged in columns, including (2k−1)-th column C(2k−1), and (2k)-th column C(2k) of K columns, K and k being positive integers, 1≤k≤(K/2). In some embodiments, the plurality of third reset signal lines Vintv are absent in the (2k−1)-th column C(2k−1), and are present in the (2k)-th column C(2k).

As used herein, the terms “(2k−1)-th column” and “(2k)-th column” are used in the context of the K columns. The array substrate may or may not include additional column(s) before the first column of the K columns and/or additional columns after the last column of the K columns. In the context of the array substrate, the term “(2k−1)-th column” does not necessarily denote an odd-numbered column, and the term “(2k)-th column does not necessarily denote an even-numbered column. In one example, the (2k−1)-th column is an odd-numbered column in the context of the K columns, but may be an even-numbered column in the context of the array substrate. In another example, the (2k−1)-th column is an odd-numbered column in the context of the K columns, and also an odd-numbered column in the context of the array substrate. In one example, the (2k)-th column is an even-numbered column in the context of the K columns, but may be an odd-numbered column in the context of the array substrate. In another example, the (2k)-th column is an even-numbered column in the context of the K columns, and also an even-numbered column in the context of the array substrate.

In some embodiments, in the first adjacent column of pixel driving circuits, the node connecting line Cin is at least partially surrounded by a reference signal line of the plurality of reference signal lines Vref. In the first adjacent column of pixel driving circuits, the respective reference signal line includes a main body MB extending along a direction substantially parallel to the second direction DR2. In some embodiments, the respective reference signal line includes a plurality of first reference signal branches Bref1. A respective first reference signal branch of the plurality of first reference signal branches Bref1 extends away from the main body MB. In one example, the respective first reference signal branch includes a first portion and a second portion. The first portion connects the second portion with the main body MB. In one example, the first portion extends along a direction substantially parallel to the first direction DR1. In another example, the second portion extends along a direction substantially parallel to the second direction DR2, The node connecting line Cln is at least partially surrounded by the main body MB on a first side, by the first portion on a second side, and by the second portion on the third side.

In some embodiments, in the (2k−1)-th column C(2k−1) of pixel driving circuits, the node connecting line Cin is at least partially surrounded by a reference signal line of the plurality of reference signal lines Vref. In the (2k−1)-th column C(2k−1) of pixel driving circuits, the respective reference signal line includes a main body MB extending along a direction substantially parallel to the second direction DR2. In some embodiments, the respective reference signal line includes a plurality of first reference signal branches Bref1. A respective first reference signal branch of the plurality of first reference signal branches Bref1 extends away from the main body MB. In one example, the respective first reference signal branch includes a first portion and a second portion. The first portion connects the second portion with the main body MB. In one example, the first portion extends along a direction substantially parallel to the first direction DR1. In another example, the second portion extends along a direction substantially parallel to the second direction DR2. The node connecting line Cln is at least partially surrounded by the main body MB on a first side, by the first portion on a second side, and by the second portion on the third side.

In some embodiments, an orthographic projection of the plurality of first reference signal branches Bref1 on a base substrate partially overlaps with an orthographic projection of a first voltage supply line of the plurality of voltage supply lines on the base substrate.

In some embodiments, in the second adjacent column of pixel driving circuits, the node connecting line Cin is at least partially surrounded by a third reset signal line of the plurality of third reset signal lines Vintv. Optionally, in the second adjacent column of pixel driving circuits, the node connecting line Cin is at least partially surrounded by a third reset signal line of the plurality of third reset signal lines Vintv on a first side, and at least partially surrounded by a first voltage signal connecting pad VCP1 on a second side.

In some embodiments, in the (2k)-th column C(2k) of pixel driving circuits, the node connecting line Cin is at least partially surrounded by a third reset signal line of the plurality of third reset signal lines Vintv. Optionally, in the (2k)-th column C(2k) of pixel driving circuits, the node connecting line Cin is at least partially surrounded by a third reset signal line of the plurality of third reset signal lines Vintv on a first side, and at least partially surrounded by a first voltage signal connecting pad VCP1 on a second side.

In some embodiments, in the first adjacent column of pixel driving circuits, first voltage signal connecting pads in different pixel driving circuits are disconnected from each other, e.g., by the plurality of first reference signal branches Bref1, respectively. In some embodiments, in the second adjacent column of pixel driving circuits, first voltage signal connecting pads in different pixel driving circuits are parts of a unitary structure extending along a direction substantially parallel to the second direction DR2.

In some embodiments, in the (2k−1)-th column C(2k−1) of pixel driving circuits, first voltage signal connecting pads in different pixel driving circuits are disconnected from each other, e.g., by the plurality of first reference signal branches Bref1, respectively. In some embodiments, in the (2k)-th column C(2k) of pixel driving circuits, first voltage signal connecting pads in different pixel driving circuits are parts of a unitary structure extending along a direction substantially parallel to the second direction DR2.

In some embodiments, in the (2k−1)-th column C(2k−1) of pixel driving circuits, first voltage signal connecting pads in multiple rows are discontinuous pads spaced apart from each other, allowing space for the plurality of first reference signal branches Bref1. In some embodiments, in the (2k)-th column C(2k) of pixel driving circuits, first voltage signal connecting pads in multiple rows are parts of a unitary structure extending throughout the multiple rows. In the (2k)-th column C(2k) of pixel driving circuits, the plurality of first reference signal branches Bref1 are absent.

In some embodiments, in the first adjacent column of pixel driving circuits, the respective reference signal line includes a main body MB extending along a direction substantially parallel to the second direction DR2, a plurality of first reference signal branches Bref1, and a plurality of second reference signal branches Bref2. Optionally, a respective first reference signal branch of the plurality of first reference signal branches Bref1 and a respective second reference signal branch of the plurality of second reference signal branches Bref2 extend away from the main body MB of the respective reference signal line on opposite sides. In some embodiments, the respective first reference signal branch of the respective reference signal line is configured to provide a reference signal to a first electrode of the seventh transistor T7 in a first adjacent pixel driving circuit in a first adjacent column of pixel driving circuits, and the respective second reference signal branch of the respective reference signal line is configured to provide a reference signal to a first electrode of the seventh transistor T7 in a second adjacent pixel driving circuit in a second adjacent column of pixel driving circuits; wherein the first adjacent pixel driving circuit and the second adjacent pixel driving circuit are in a same row.

In some embodiments, the respective first reference signal branch has a first length l1 along a direction substantially parallel to the first direction DR1, and the respective second reference signal branch has a second length l2 along a direction substantially parallel to the first direction DR1. Optionally, the first length l1 is greater than the second length l2, e.g., by at least 10%, by at least 20%, by at least 30%, by at least 40%, by at least 50%, by at least 60%, by at least 70%, by at least 80%, by at least 90%, by at least 100%, by at least 110%, by at least 120%, by at least 130%, by at least 140%, by at least 150%, by at least 160%, by at least 170%, by at least 180%, by at least 190%, or by at least 200%.

In some embodiments, the array substrate includes an interconnected reset signal network. Various appropriate implementations may be practiced in the present disclosure. In some embodiments, the interconnected reset signal network includes a plurality of third reset signal lines Vintv and a plurality of first reset signal lines Vint1 interconnected together. In some embodiments, the interconnected reset signal network includes a plurality of third reset signal lines Vintv and a plurality of second reset signal lines Vint2 interconnected together. In some embodiments, the interconnected reset signal network includes a plurality of third reset signal lines Vintv, a plurality of first reset signal lines Vint1, and a plurality of second reset signal lines Vint2 interconnected together.

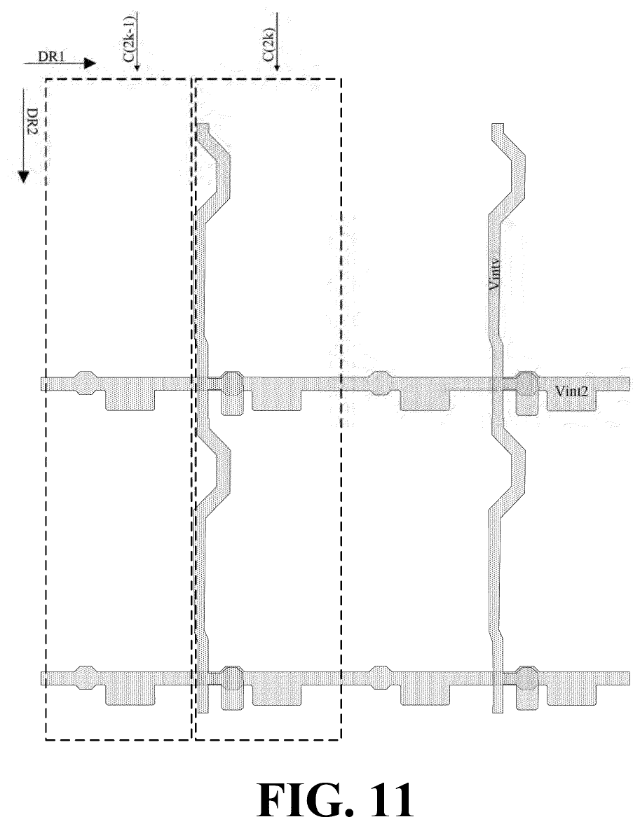

FIG. 11 illustrates the structure of an interconnected reset network in some embodiments according to the present disclosure. Referring to FIG. 11, the interconnected reset network in some embodiments includes a plurality of third reset signal lines Vintv and a plurality of second reset signal lines Vint2. Optionally, the plurality of second reset signal lines Vint2 extend along a direction substantially parallel to the first direction DR1. Optionally, the plurality of third reset signal lines Vintv extend along a direction substantially parallel to the second direction DR2. Optionally, the plurality of second reset signal lines Vint2 are in a layer different from the plurality of third reset signal lines Vintv. In one example, the plurality of second reset signal lines Vint2 are in the second conductive layer. In another example, the plurality of third reset signal lines Vintv are in the first signal line layer. Optionally, a respective third reset signal line of the plurality of third reset signal lines Vintv is connected to a respective second reset signal line of the plurality of second reset signal lines Vint2 through a via extending through the inter-layer dielectric layer.

Optionally, the plurality of third reset signal lines Vintv are absent in the (2k−1)-th column C(2k−1) of pixel driving circuits, and are present in the (2k)-th column C(2k) of pixel driving circuits.

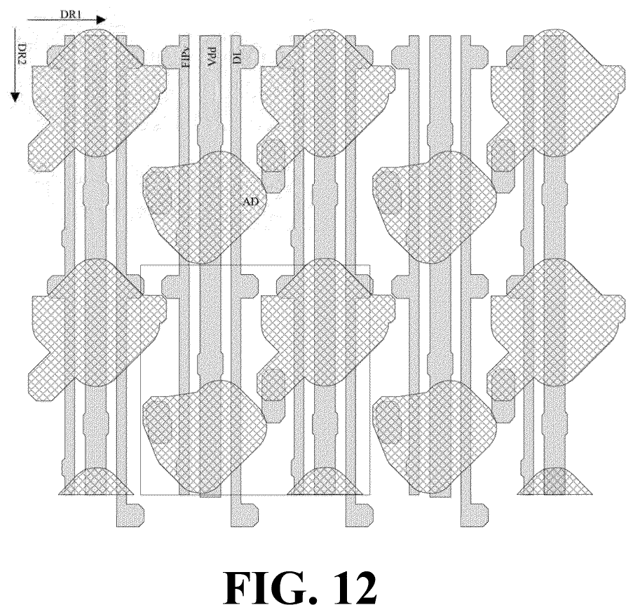

FIG. 12 illustrates a layout of signal lines in a third signal line layer and an anode layer in a portion of an array substrate in some embodiments according to the present disclosure. Referring to FIG. 12, in some embodiments, an orthographic projection of the anode AD on a base substrate at least partially overlaps with an orthographic projection of a respective second fanout connecting line of the plurality of second fanout connecting lines FIPv on the base substrate; at least partially overlaps with an orthographic projection of a respective first voltage supply line of the plurality of first voltage supply lines Vdd on the base substrate; and at least partially overlaps with an orthographic projection of a respective data line of the plurality of data lines DL on the base substrate.

The inventors of the present disclosure discover that a degree of evenness of anodes in a display panel could adversely affect image display. For example, color shift may result from the anodes being tilted. It is discovered in the present disclosure that signal lines underneath the anodes could significantly affect the degree the anodes being tilted. In one example, underneath an anode, at one side a signal line is disposed while the other side is absent of a signal line. This results in an uneven surface of a planarization layer on top of the signal line. The uneven surface of the planarization layer in turn results in the anode on top of the planarization layer being tilted. For example, the presence of a signal line underneath a left side portion of a planarization layer results in an uneven surface of the planarization, which in turn results in an anode on top of the planarization layer being tilted toward the right side. The tilted anode reflects more light toward the right side of the display panel. In the display panel, anodes associated with subpixels of different colors have different tilted angles, thus light reflected by anodes in subpixels of different colors reflect light of different colors respectively at different angles. The accumulated effect of this issue lead to color shift at a large viewing angle.

In the present disclosure, by having the orthographic projection of the plurality of anodes AD on the base substrate at least partially overlaps with the orthographic projection of the respective second fanout connecting line of the plurality of second fanout connecting lines FIPv on the base substrate; at least partially overlaps with the orthographic projection of the respective first voltage supply line of the plurality of first voltage supply lines Vdd on the base substrate; and at least partially overlaps with the orthographic projection of the respective data line of the plurality of data lines DL on the base substrate, the array substrate achieves an even surface of the planarization layer underneath the anodes. As a result, color shift issue can be alleviated.

In some embodiments, the respective second fanout connecting line of the plurality of second fanout connecting lines FIPv, the respective first voltage supply line of the plurality of first voltage supply lines Vdd, and the respective data line of the plurality of data lines DL cross over the anode AD, respectively. In some embodiments, the respective second fanout connecting line of the plurality of second fanout connecting lines FIPv, the respective first voltage supply line of the plurality of first voltage supply lines Vdd, and the respective data line of the plurality of data lines DL are substantially evenly distributed along the first direction DR1 with respect to the anode AD. For example, portions of the respective second fanout connecting line of the plurality of second fanout connecting lines FIPv, the respective first voltage supply line of the plurality of first voltage supply lines Vdd, and the respective data line of the plurality of data lines DL, in a region crossing over the anode AD, are equi-spaced. In another example, portions of the respective second fanout connecting line of the plurality of second fanout connecting lines FIPv, the respective first voltage supply line of the plurality of first voltage supply lines Vdd, and the respective data line of the plurality of data lines DL, in a region crossing over the anode AD, have a substantial (e.g., at least 80%, at least 85%, at least 90%, at least 95%, or at least 99%) mirror symmetry with respect to a plane perpendicular to the anode AD and intersecting the anode AD. The inventors of the present disclosure discover that, by having the intricate structure of anodes and signal lines according to the present disclosure, an even surface of the planarization layer underneath the anode AD can be achieved. As a result, color shift issue can be alleviated.

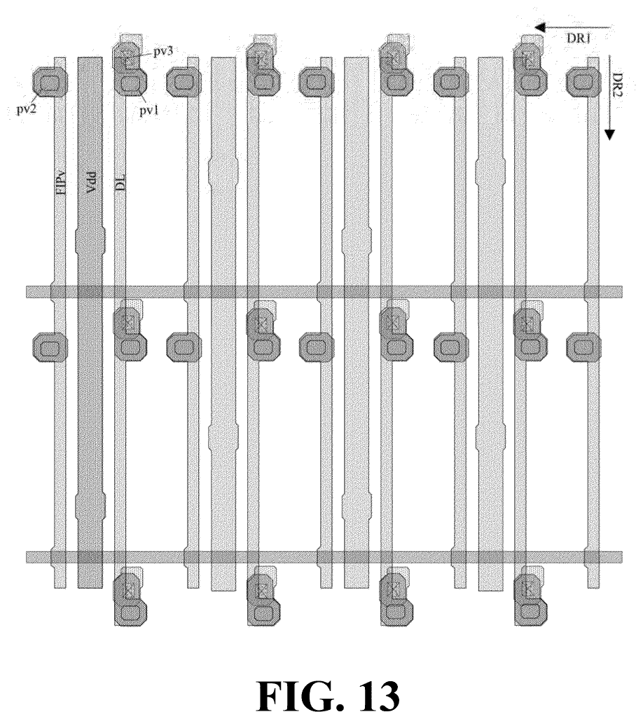

FIG. 13 illustrates connections between signal lines in a third signal line layer and underlying pads through pad connecting vias in a portion of an array substrate in some embodiments according to the present disclosure. Referring to FIG. 13, FIG. 3A, FIG. 3G, FIG. 3I, and FIG. 3K, the respective data line of the plurality of data lines DL is connected to the second data signal connecting pad DCP2 through a first pad connecting via pv1. The respective second fanout connecting line of the plurality of second fanout connecting lines FIPv is connected to the fanout connecting pad FCP through a second pad connecting via pv2. The second data signal connecting pad DCP2 is connected to the first data signal connecting pad DCP1 through a third pad connecting via pv3.

In some embodiments, the first pad connecting via pv1 and the second pad connecting via pv2 respectively extend through the second planarization layer PLN2. In some embodiments, the third pad connecting via pv3 extends through the first planarization layer PLN1.

In some embodiments, the first pad connecting via pv1 and the third pad connecting via pv3 are located at different positions. Optionally, an orthographic projection of a conductive material extending through the first pad connecting via pv1 on a base substrate is substantially non-overlapping (e.g., at least 80) % non-overlapping, at least 90% non-overlapping, at least 95% non-overlapping, at least 99% non-overlapping, or completely non-overlapping) with an orthographic projection of a conductive material extending through the third pad connecting via pv3 on the base substrate.

In some embodiments, the first pad connecting via pv1 has a first elongated shape in a cross-section along a plane having the plurality of data lines DL, the plurality of first voltage supply lines Vdd, and the plurality of second fanout connecting lines FIPv. The first elongated shape has a longitudinal side along a direction substantially parallel to the first direction DR1. In some embodiments, the second pad connecting via pv2 has a second elongated shape in a cross-section along a plane having the plurality of data lines DL, the plurality of first voltage supply lines Vdd, and the plurality of second fanout connecting lines FIPv. The second elongated shape has a longitudinal side along a direction substantially parallel to the first direction DR1. In some embodiments, the third pad connecting via pv3 has a third elongated shape in a cross-section along a plane having the plurality of data lines DL, the plurality of first voltage supply lines Vdd, and the plurality of second fanout connecting lines FIPv. The third elongated shape has a longitudinal side along a direction substantially parallel to the second direction DR2.

In some embodiments, an orthographic projection of the first pad connecting via pv1 on a base substrate is non-overlapping with an orthographic projection of the plurality of subpixel apertures SA on the base substrate. In alternative embodiments, an orthographic projection of the first pad connecting via pv1 on a base substrate partially overlaps with an orthographic projection of the plurality of subpixel apertures SA (for example, a subpixel aperture for a blue subpixel) on the base substrate. Optionally, no more than 50% (e.g., no more than 45%, no more than 40%, no more than 35%, no more than 30%, no more than 25%, no more than 20%, no more than 15%, no more than 10%, no more than 5%, or no more than 1%) of the orthographic projection of the first pad connecting via pv1 on the base substrate overlaps with the orthographic projection of the plurality of subpixel apertures SA on the base substrate. The inventors of the present disclosure discover that, by having this unique structure, the array substrate achieves an even surface of the planarization layer underneath the anodes. As a result, color shift issue can be alleviated.

In some embodiments, an orthographic projection of the second pad connecting via pv2 on a base substrate is non-overlapping with an orthographic projection of the plurality of subpixel apertures SA on the base substrate. In alternative embodiments, an orthographic projection of the second pad connecting via pv2 on a base substrate partially overlaps with an orthographic projection of the plurality of subpixel apertures SA (for example, a subpixel aperture for a blue subpixel) on the base substrate. Optionally, no more than 50% (e.g., no more than 45%, no more than 40%, no more than 35%, no more than 30%, no more than 25%, no more than 20%, no more than 15%, no more than 10%, no more than 5%, or no more than 1%) of the orthographic projection of the second pad connecting via pv2 on the base substrate overlaps with the orthographic projection of the plurality of subpixel apertures SA on the base substrate. The inventors of the present disclosure discover that, by having this unique structure, the array substrate achieves an even surface of the planarization layer underneath the anodes. As a result, color shift issue can be alleviated.

In some embodiments, a respective subpixel aperture of the plurality of subpixel apertures has a periphery comprising one or more straight line portions and one or more curved line portions. In some embodiments, when the orthographic projection of the first pad connecting via pv1 and/or the second pad connecting via pv2 on a base substrate partially overlaps with an orthographic projection of a respective subpixel aperture (e.g., a subpixel aperture for a blue subpixel) of the plurality of subpixel apertures SA on the base substrate, the first pad connecting via pv1 and/or the second pad connecting via pv2 are located at positions corresponding to the one or more straight line portions of the periphery of the respective subpixel aperture. For example, the orthographic projection of the first pad connecting via pv1 and/or the second pad connecting via pv2 on a base substrate is non-overlapping with an orthographic projection of the one or more curved line portions of the periphery of the respective subpixel aperture on the base substrate; and is partially overlapping with an orthographic projection of the one or more straight line portions of the periphery of the respective subpixel aperture on the base substrate. The inventors of the present disclosure discover that, by having this unique structure, the array substrate achieves an even surface of the planarization layer underneath the anodes. As a result, color shift issue can be alleviated.

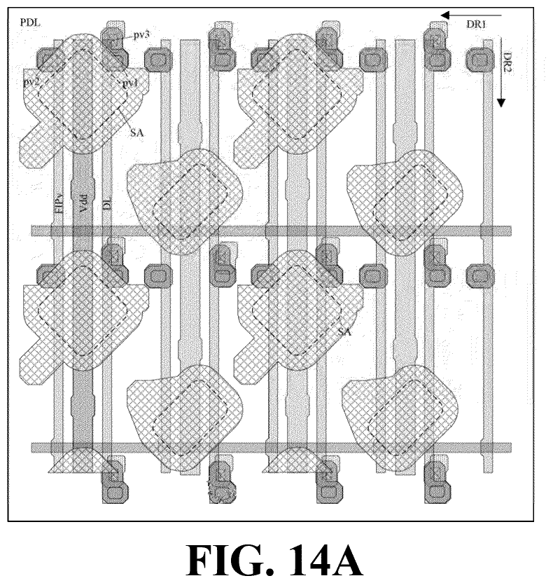

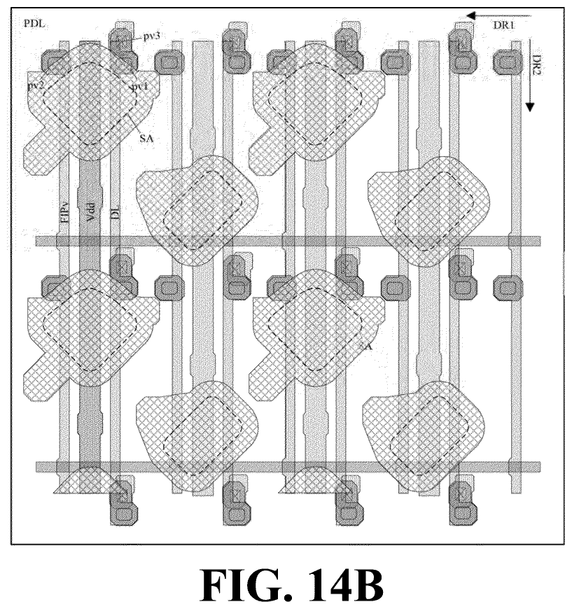

FIG. 14A illustrates pad connecting vias, an anode layer, and a pixel definition layer in a portion of an array substrate in some embodiments according to the present disclosure. FIG. 14B illustrates pad connecting vias, an anode layer, and a pixel definition layer in a portion of an array substrate in some embodiments according to the present disclosure. The array substrate depicted in FIG. 14B differs from the array substrate depicted in FIG. 14A in that at least one anode (and optionally at least one corresponding subpixel aperture) in FIG. 14B has a different shape from a counterpart depicted in FIG. 14A. Referring to FIG. 14A and FIG. 14B, in some embodiments, by having the longitudinal side of the first elongated shape and the longitudinal side of the second elongated shape extend along a direction substantially parallel to the first direction DR1, an orthographic projection of a pixel definition layer PDL on a base substrate covers an orthographic projection of a conductive material extending through the first pad connecting via pv1 on the base substrate, and covers an orthographic projection of a conductive material extending through the second pad connecting via pv2 on the base substrate, Optionally, an orthographic projection of a light emitting material in the plurality of subpixel apertures on the base substrate is substantially non-overlapping (e.g., at least 80% non-overlapping, at least 90% non-overlapping, at least 95% non-overlapping, at least 99% non-overlapping, or completely non-overlapping) with the orthographic projection of a conductive material extending through the first pad connecting via pv1 on the base substrate, and is non-overlapping with the orthographic projection of a conductive material extending through the second pad connecting via pv2 on the base substrate. The inventors of the present disclosure discover that, by having the intricate structure of anodes and pad connecting vías according to the present disclosure, an even surface of the planarization layer underneath the anode AD can be achieved. As a result, color shift issue can be alleviated.

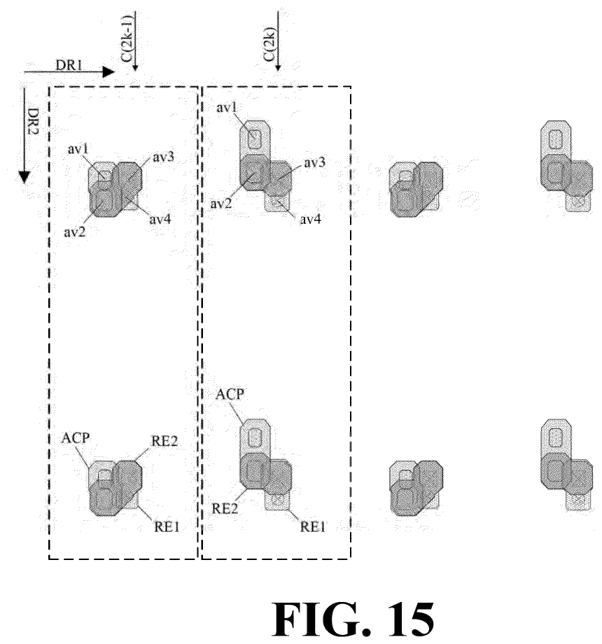

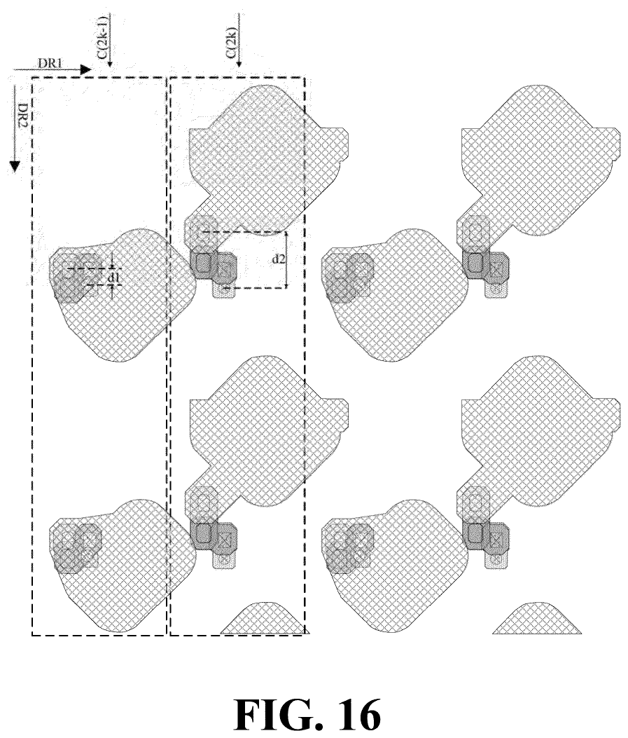

FIG. 15 illustrates connections between an anode connecting pad, a first relay electrode, and a second relay electrode in a portion of an array substrate in some embodiments according to the present disclosure. FIG. 16 illustrates connections between an anode, an anode connecting pad, a first relay electrode, and a second relay electrode in a portion of an array substrate in some embodiments according to the present disclosure. Referring to FIG. 15 and FIG. 16, in some embodiments, the array substrate includes a first anode connecting via av1, a second anode connecting via av2, a third anode connecting via av3, and a fourth anode connecting via av4. The anode AD is connected to the anode connecting pad ACP through the first anode connecting via av1. The anode connecting pad ACP is connected to the second relay electrode RE2 through the second anode connecting via av2. The second relay electrode RE2 is connected to the first relay electrode RE1 through the third anode connecting via av3. The first relay electrode RE1 is connected to the second electrode of the fifth transistor T5 (the fourth node N4) through the fourth anode connecting via av4.

In some embodiments, an arrangement of the anode connecting pad, the first relay electrode, and the second relay electrode in a first adjacent column of pixel driving circuits is different from an arrangement of the anode connecting pad, the first relay electrode, and the second relay electrode in a second adjacent column of pixel driving circuits. In the first adjacent column of pixel driving circuits, the first anode connecting via av1 is spaced apart from the fourth anode connecting via av4 by a first distance d1 along the second direction DR2. In the second adjacent column of pixel driving circuits, the first anode connecting via av1 is spaced apart from the fourth anode connecting via av4 by a second distance d2 along the second direction DR2. Optionally, the first distance d1 and the second distance d2 are different from each other. Optionally, the second distance d2 is greater than the first distance d1 by at least 10%, e.g., by at least 20%, by at least 30%, by at least 40%, by at least 50%, by at least 60%, by at least 70%, by at least 80%, by at least 90%, by at least 100%, by at least 110%, e.g., by at least 120%, by at least 130%, by at least 140%, by at least 150%, by at least 160%, by at least 170%, by at least 180%, by at least 190%, or by at least 200%.

In the first adjacent column of pixel driving circuits, an orthographic projection of the anode AD on a base substrate at least partially overlaps with an orthographic projection of the anode connecting pad ACP on the base substrate, at least partially overlaps with an orthographic projection of the second relay electrode RE2 on the base substrate, and at least partially overlaps with an orthographic projection of the first relay electrode RE1 on the base substrate. Optionally, in the first adjacent column of pixel driving circuits, the orthographic projection of the anode AD on the base substrate substantially covers (e.g., covers at least 80%), covers at least 85%, covers at least 90%, covers at least 95%, covers at least 99%, or completely covers) the orthographic projection of the anode connecting pad ACP on the base substrate, substantially covers (e.g., covers at least 80%, covers at least 85%, covers at least 90%, covers at least 95%, covers at least 99%, or completely covers) the orthographic projection of the second relay electrode RE2 on the base substrate, and substantially covers (e.g., covers at least 80%, covers at least 85%, covers at least 90%, covers at least 95%, covers at least 99%, or completely covers) the orthographic projection of the first relay electrode RE1 on the base substrate.

In the second adjacent column of pixel driving circuits, an orthographic projection of the anode AD on a base substrate partially overlaps with an orthographic projection of the anode connecting pad ACP on the base substrate, is at least partially non-overlapping with an orthographic projection of the second relay electrode RE2 on the base substrate, and is at least partially non-overlapping with an orthographic projection of the first relay electrode RE1 on the base substrate. Optionally, in the second adjacent column of pixel driving circuits, the orthographic projection of the anode AD on a base substrate partially overlaps with an orthographic projection of the anode connecting pad ACP on the base substrate, is substantially non-overlapping (e.g., at least 80% non-overlapping, at least 90% non-overlapping, at least 95% non-overlapping, at least 99% non-overlapping, or completely non-overlapping) with the orthographic projection of the second relay electrode RE2 on the base substrate, and is substantially non-overlapping (e.g., at least 811% non-overlapping, at least 90% non-overlapping, at least 95% non-overlapping, at least 99% non-overlapping, or completely non-overlapping) with the orthographic projection of the first relay electrode RE1 on the base substrate.

In some embodiments, an arrangement of the anode connecting pad, the first relay electrode, and the second relay electrode in the (2k−1)-th column C(2k−1) of pixel driving circuits is different from an arrangement of the anode connecting pad, the first relay electrode, and the second relay electrode in the (2k)-th column C(2k) of pixel driving circuits. In the (2k−1)-th column C(2k−1) of pixel driving circuits, the first anode connecting via av1 is spaced apart from the fourth anode connecting via av4 by a first distance d1 along the second direction DR2. In the (2k)-th column C(2k) of pixel driving circuits, the first anode connecting via av1 is spaced apart from the fourth anode connecting via av4 by a second distance d2 along the second direction DR2. Optionally, the first distance d1 and the second distance d2 are different from each other. Optionally, the second distance d2 is greater than the first distance d1 by at least 10%, e.g., by at least 20%, by at least 30%, by at least 40%, by at least 50%, by at least 60%, by at least 70%, by at least 80%, by at least 90%, by at least 100%, by at least 110%, e.g., by at least 120%, by at least 130%, by at least 140%, by at least 150%, by at least 160%, by at least 170%, by at least 180%, by at least 190%, or by at least 200%.

In the (2k−1)-th column C(2k−1) of pixel driving circuits, an orthographic projection of the anode AD on a base substrate at least partially overlaps with an orthographic projection of the anode connecting pad ACP on the base substrate, at least partially overlaps with an orthographic projection of the second relay electrode RE2 on the base substrate, and at least partially overlaps with an orthographic projection of the first relay electrode RE1 on the base substrate. Optionally, in the (2k−1)-th column C(2k−1) of pixel driving circuits, the orthographic projection of the anode AD on the base substrate substantially covers (e.g., covers at least 80%, covers at least 85%, covers at least 90%, covers at least 95%, covers at least 99%, or completely covers) the orthographic projection of the anode connecting pad ACP on the base substrate, substantially covers (e.g., covers at least 80%, covers at least 85%, covers at least 90%, covers at least 95%, covers at least 99%, or completely covers) the orthographic projection of the second relay electrode RE2 on the base substrate, and substantially covers (e.g., covers at least 80%, covers at least 85%, covers at least 90%, covers at least 95%, covers at least 99%, or completely covers) the orthographic projection of the first relay electrode RE1 on the base substrate.

In the (2k)-th column C(2k) of pixel driving circuits, an orthographic projection of the anode AD on a base substrate partially overlaps with an orthographic projection of the anode connecting pad ACP on the base substrate, is at least partially non-overlapping with an orthographic projection of the second relay electrode RE2 on the base substrate, and is at least partially non-overlapping with an orthographic projection of the first relay electrode RE1 on the base substrate. Optionally, in the (2k)-th column ((2k) of pixel driving circuits, the orthographic projection of the anode AD on a base substrate partially overlaps with an orthographic projection of the anode connecting pad ACP on the base substrate, is substantially non-overlapping (e.g., at least 80% non-overlapping, at least 90% non-overlapping, at least 95% non-overlapping, at least 99% non-overlapping, or completely non-overlapping) with the orthographic projection of the second relay electrode RE2 on the base substrate, and is substantially non-overlapping (e.g., at least 80% non-overlapping, at least 90% non-overlapping, at least 95% non-overlapping, at least 99% non-overlapping, or completely non-overlapping) with the orthographic projection of the first relay electrode RE1 on the base substrate.

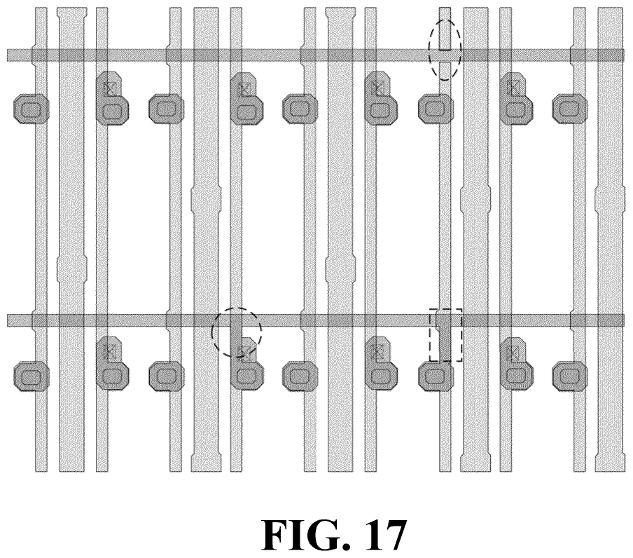

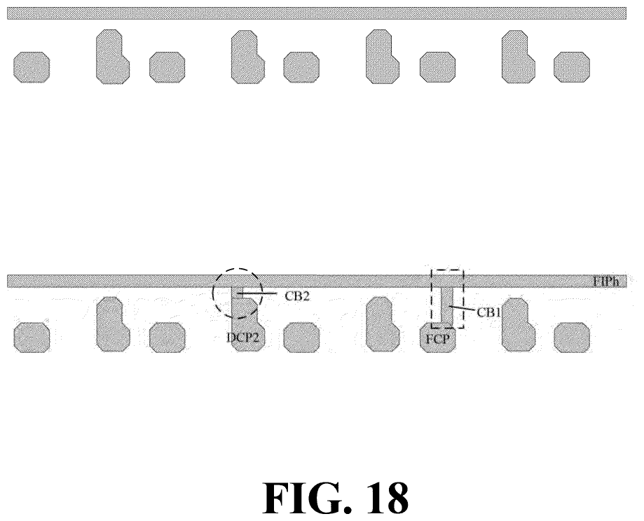

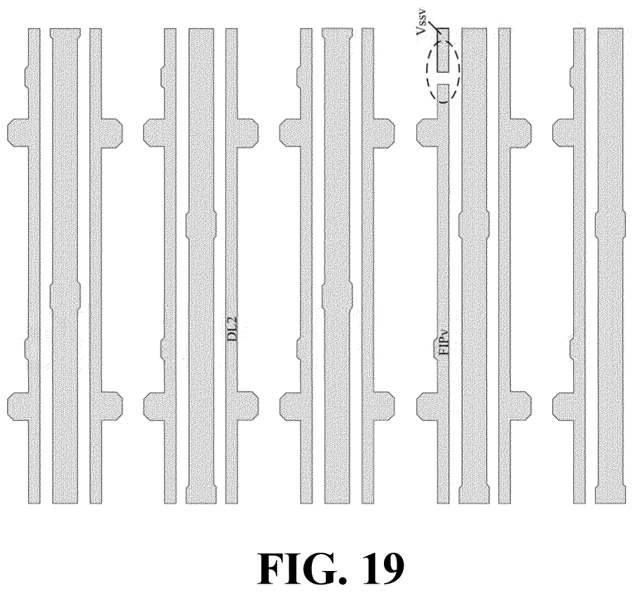

FIG. 17 illustrates a layout of signal lines involved in data signal transmission to a respective second data line of a plurality of second data lines in a portion of an array substrate in some embodiments according to the present disclosure. FIG. 18 illustrates a layout of signal lines in a second signal line layer involved in data signal transmission to a respective second data line of a plurality of second data lines in a portion of an array substrate in some embodiments according to the present disclosure. FIG. 19 illustrates a layout of signal lines in a third signal line layer involved in data signal transmission to a respective second data line of a plurality of second data lines in a portion of an array substrate in some embodiments according to the present disclosure. Referring to FIG. 17 to FIG. 19, the second signal line layer in some embodiments includes a plurality of first fanout connecting lines FIPh, a second data signal connecting pad DCP2, a fanout connecting pad FCP, a first connecting bridge CB1, and a second connecting bridge CB2. The third signal line layer in some embodiments includes a plurality of second data lines DL2 and a plurality of second fanout connecting lines FIPv.

In some embodiments, data signals are transmitted from a data driving circuit to a respective second data line of the plurality of second data lines DL2 sequentially through a respective second fanout connecting line of the plurality of second fanout connecting lines FIPv, the fanout connecting pad FCP, the first connecting bridge CB1, a respective first fanout connecting line of the plurality of first fanout connecting lines FIPh, the second connecting bridge CB2, and the second data signal connecting pad DCP2. The first connecting bridge CB1 is present where a second fanout connecting line of the plurality of second fanout connecting lines FIPv is connected to a first fanout connecting line of the plurality of first fanout connecting lines FIPh, and is absent elsewhere. The second connecting bridge CB2 is present where a second data line of the plurality of second data lines DL2 is connected to a first fanout connecting line of the plurality of first fanout connecting lines FIPh, and is absent elsewhere.

In some embodiments, the first connecting bridge CB1, the fanout connecting pad FCP, and the respective first fanout connecting line of the plurality of first fanout connecting lines FIPh are parts of a unitary structure. In some embodiments, the second connecting bridge CB2, the second data signal connecting pad DCP2, and the respective first fanout connecting line of the plurality of first fanout connecting lines FIPh are parts of a unitary structure. In some embodiments, the first connecting bridge CB1, the fanout connecting pad FCP, the second connecting bridge CB2, the second data signal connecting pad DCP2, and the respective first fanout connecting line of the plurality of first fanout connecting lines FIPh are parts of a unitary structure.

In some embodiments, an orthographic projection of the first connecting bridge CB1 on a base substrate at least partially overlaps with an orthographic projection of the respective second fanout connecting line of the plurality of second fanout connecting lines FIPv on the base substrate. Optionally, the orthographic projection of the respective second fanout connecting line of the plurality of second fanout connecting lines FIPv on the base substrate covers the orthographic projection of the first connecting bridge CB1 on the base substrate. The inventors of the present disclosure discover that this structure enhances display uniformity.

In some embodiments, an orthographic projection of the second connecting bridge CB2 on a base substrate at least partially overlaps with an orthographic projection of the respective second data line of the plurality of second data lines DL2 on the base substrate. Optionally, the orthographic projection of the respective second data line of the plurality of second data lines DL2 on the base substrate covers the orthographic projection of the second connecting bridge CB2 on the base substrate. The inventors of the present disclosure discover that this structure enhances display uniformity.

In some embodiments, in at least one column of subpixels, an individual second fanout connecting line of the plurality of second fanout connecting lines FIPv is disconnected from an individual second voltage supply line of the plurality of second voltage supply lines Vssv by a line break (denoted by an elliptical mark). An insulating material of an insulating layer (e.g., the third planarization layer PLN3) is in the line break. An orthographic projection of an individual first fanout connecting line of the plurality of first fanout connecting lines FIPh on a base substrate at least partially overlaps with an orthographic projection of the insulating material in the line break on the base substrate. Optionally, the orthographic projection of an individual first fanout connecting line of the plurality of first fanout connecting lines FIPh on a base substrate substantially covers (e.g., covers at least 80%, covers at least 85%, covers at least 90%, covers at least 95%, covers at least 99%, or completely covers) the orthographic projection of the insulating material in the line break on the base substrate. The inventors of the present disclosure discover that this structure enhances display uniformity.

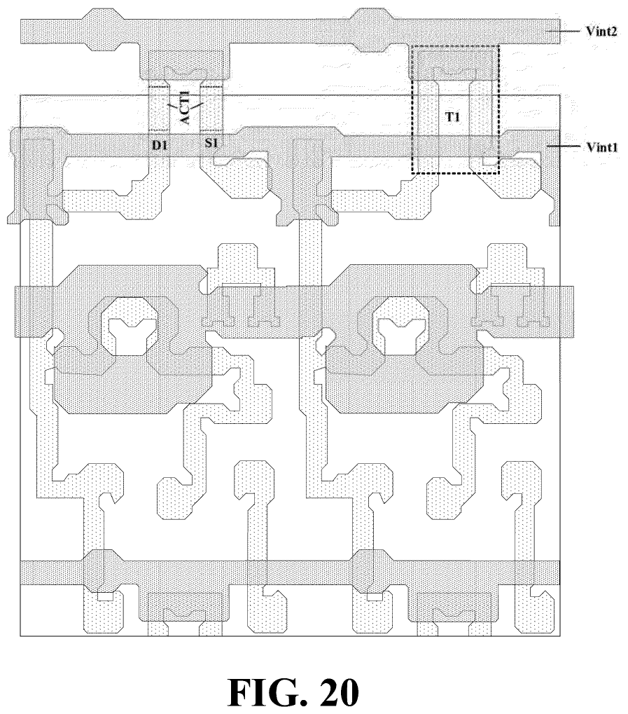

FIG. 20 is a diagram illustrating the structure of a semiconductor material layer and a second conductive layer in an array substrate in some embodiments according to the present disclosure. Referring to FIG. 20, in some embodiments, an orthographic projection of a respective second reset signal line of the plurality of second reset signal lines Vint2 on a base substrate at least partially overlaps with an orthographic projection of a portion of the semiconductor material layer between two active layer portions (e.g., two channel parts) of the first transistor T1 on the base substrate. The inventors of the present disclosure discover that this unique structure enhances stability of the first transistor T1.

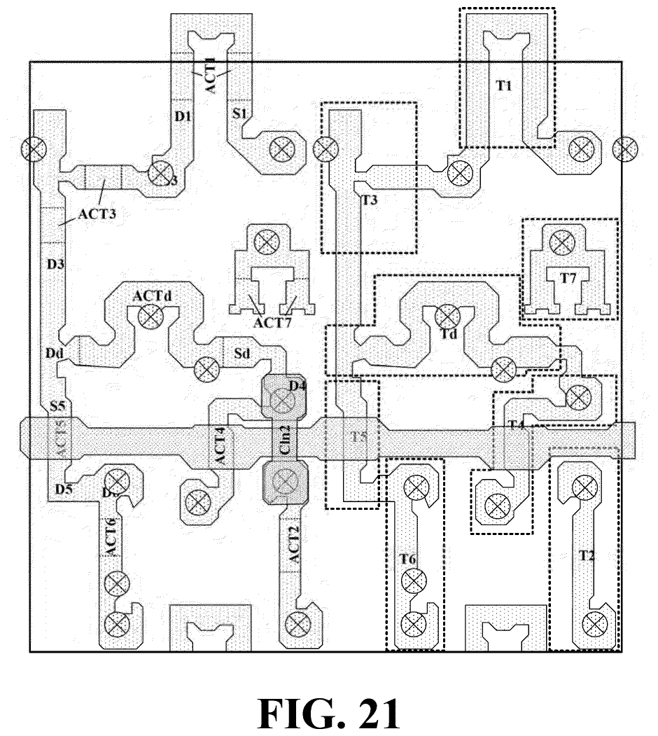

FIG. 21 is a diagram illustrating the structure of a semiconductor material layer and a respective light emitting control signal line, and a second node connecting line in an array substrate in some embodiments according to the present disclosure. Referring to FIG. 21, FIG. 3D, and FIG. 3G, in some embodiments, the first signal line layer further includes a second node connecting line Cln2 connecting a second electrode D2 of the second transistor with a first electrode Sd of the driving transistor Td. The second node connecting line Cln2 crosses over a respective light emitting control signal line in the first conductive layer. A portion of the semiconductor material layer comprising the first electrode Sd of the driving transistor Td and the second electrode D4 of the fourth transistor T4 protrudes toward the second node connecting line Cln2.

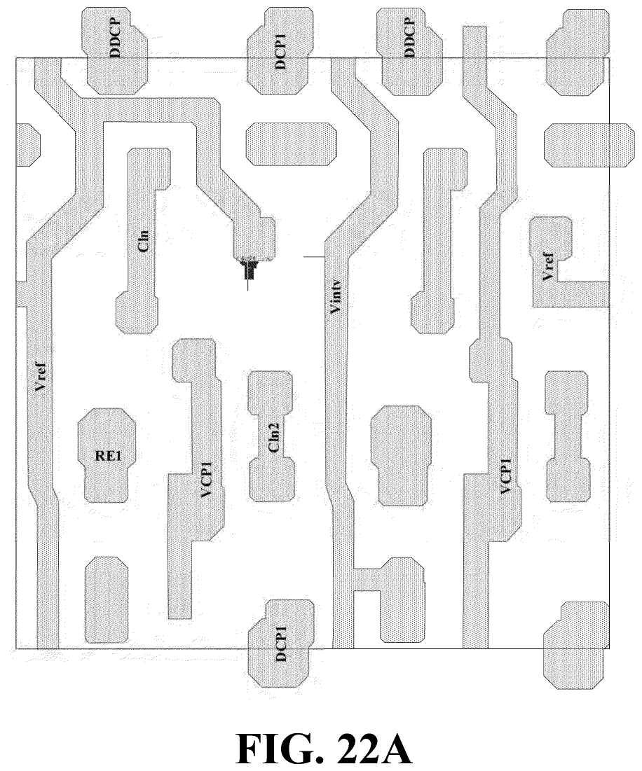

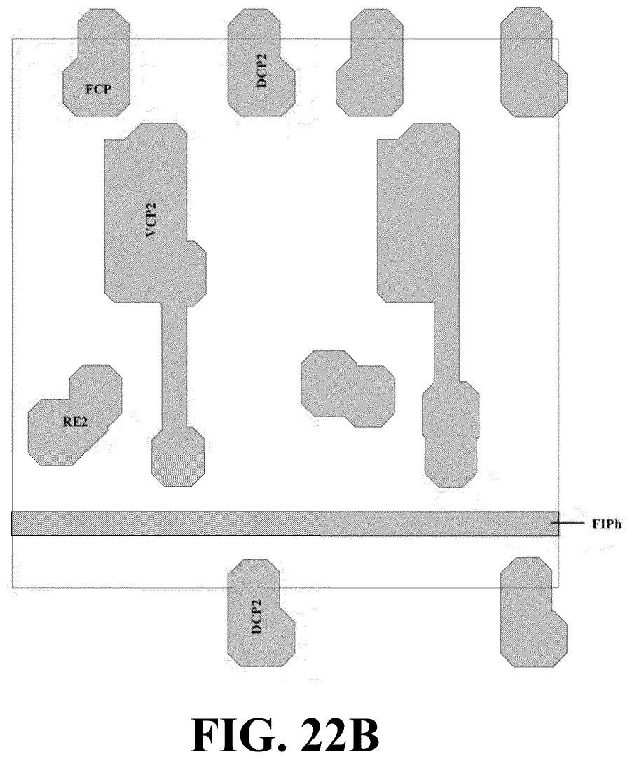

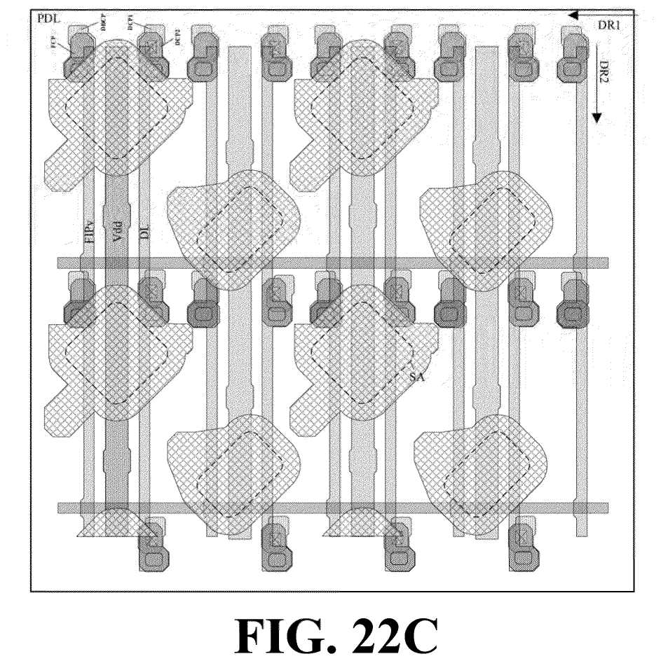

FIG. 22A is a diagram illustrating the structure of a first signal line layer in an array substrate in some embodiments according to the present disclosure. FIG. 22B is a diagram illustrating the structure of a second signal line layer in an array substrate in some embodiments according to the present disclosure. FIG. 22C illustrates pad connecting vias, an anode layer, and a pixel definition layer in a portion of an array substrate in some embodiments according to the present disclosure. Referring to FIG. 22A to FIG. 22C, in some embodiments, the first signal line layer further includes a dummy data signal connecting pad DDCP. Optionally, the dummy data signal connecting pad DDCP has a shape so that the dummy data signal connecting pad DDCP and a first data signal connecting pad DCP1 has a substantial (e.g., at least 80%, at least 85%, at least 90%, at least 95%, or at least 99%) mirror symmetry with respect to an individual first voltage supply line of the plurality of first voltage supply lines Vdd.

In some embodiments, the fanout connecting pad FCP has a shape so that the fanout connecting pad FCP and a second data signal connecting pad DCP2 has a substantial (e.g., at least 80%, at least 85%, at least 90%, at least 95%, or at least 99%) mirror symmetry with respect to an individual first voltage supply line of the plurality of first voltage supply lines Vdd.

In some embodiments, in at least one subpixel of the array substrate, portions of the respective second fanout connecting line of the plurality of second fanout connecting lines FIPv, the respective first voltage supply line of the plurality of first voltage supply lines Vdd, and the respective data line of the plurality of data lines DL, in a region crossing over the anode AD, have a substantial (e.g., at least 80%, at least 85%, at least 90%, at least 95%, or at least 99%) mirror symmetry with respect to a plane perpendicular to the anode AD and intersecting the anode AD. Moreover, in at least one subpixel of the array substrate, a first group of pads and a second group of pads have a substantial (e.g., at least 80%, at least 85%, at least 90%, at least 95%, or at least 99%) mirror symmetry with respect to a plane perpendicular to the anode AD and intersecting the anode AD. The first group of pads includes the fanout connecting pad FCP and the dummy data signal connecting pad DDCP. The second group of pads includes the first data signal connecting pad DCP1 and the second data signal connecting pad DCP2. In one example, an orthographic projection of the first group of pads on a base substrate at least partially overlaps with an orthographic projection of the anode AD on the base substrate; and an orthographic projection of the second group of pads on the base substrate at least partially overlaps with an orthographic projection of the anode AD on the base substrate. In an alternative example, an orthographic projection of the first group of pads on a base substrate is non-overlapping with an orthographic projection of the anode AD on the base substrate; and an orthographic projection of the second group of pads on the base substrate is non-overlapping with an orthographic projection of the anode AD on the base substrate. The inventors of the present disclosure discover that, by having this unique structure, an even surface of the planarization layer underneath the anode AD can be achieved. As a result, color shift issue can be alleviated.

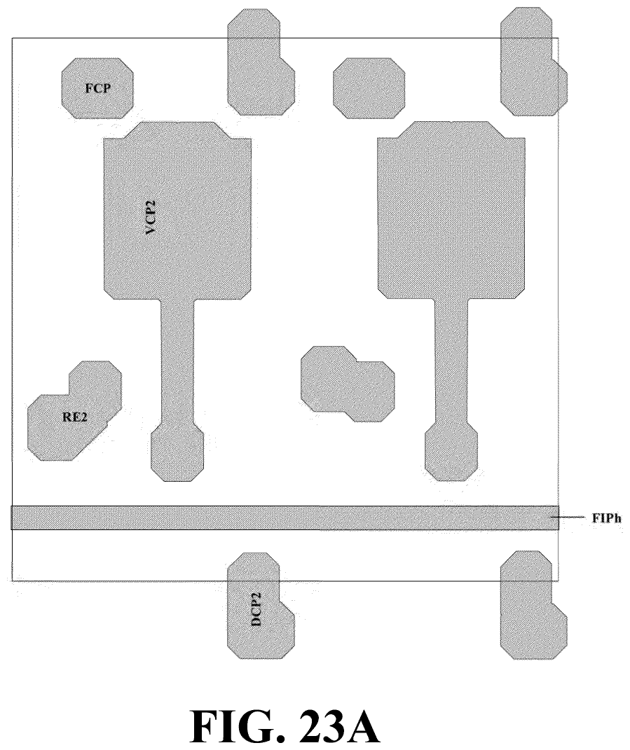

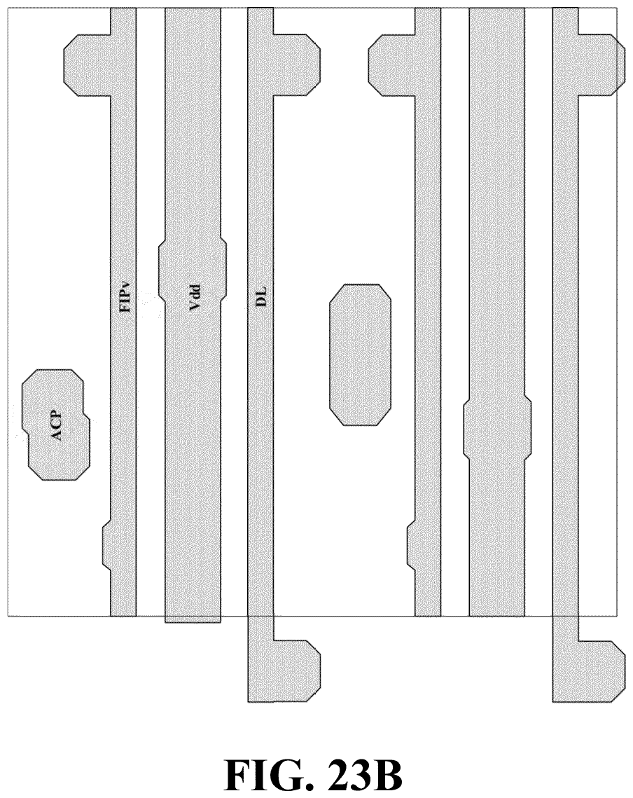

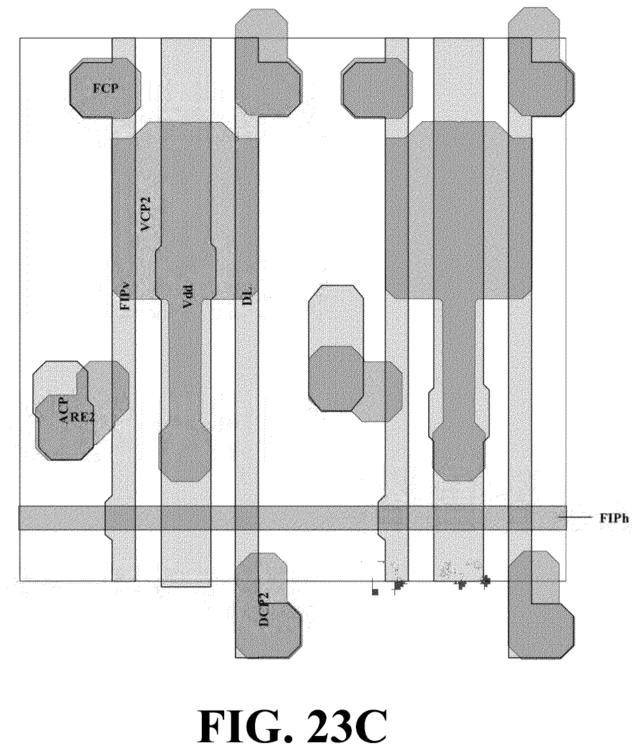

FIG. 23A is a diagram illustrating the structure of a second signal line layer in an array substrate in some embodiments according to the present disclosure. FIG. 23B is a diagram illustrating the structure of a third signal line layer in an array substrate in some embodiments according to the present disclosure. FIG. 23C is a diagram illustrating the structure of a second signal line layer and a third signal line layer in an array substrate in some embodiments according to the present disclosure. Referring to FIG. 23A to FIG. 23C, in some embodiments, an orthographic projection of the second voltage signal connecting pad VCP2 on a base substrate at least partially overlaps with an orthographic projection of the respective second fanout connecting line of the plurality of second fanout connecting lines FIPv, the respective first voltage supply line of the plurality of first voltage supply lines Vdd, and the respective data line of the plurality of data lines DL on the base substrate. The inventors of the present disclosure discover that, by having this unique structure, an even surface of the planarization layer underneath the anode AD can be achieved. As a result, color shift issue can be alleviated.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating an array substrate. In some embodiments, the method includes forming a plurality of data lines; forming a plurality of second fanout connecting lines; and forming a plurality of first voltage supply lines. Optionally, in at least one subpixel of the array substrate, an individual data line of the plurality of data lines and an individual second fanout connecting line of the plurality of second fanout connecting lines have a substantial mirror symmetry with respect to an individual first voltage supply line of the plurality of first voltage supply lines.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising:
a plurality of data lines;
a plurality of second fanout connecting lines; and
a plurality of first voltage supply lines;
wherein, in at least one subpixel of the array substrate, an individual data line of the plurality of data lines and an individual second fanout connecting line of the plurality of second fanout connecting lines have a substantial mirror symmetry with respect to an individual first voltage supply line of the plurality of first voltage supply lines.

2. The array substrate of claim 1, wherein the plurality of data lines, the plurality of second fanout connecting lines, and the plurality of first voltage supply lines are in a same layer.

3. The array substrate of claim 1, further comprising an anode on a side of the plurality of data lines, the plurality of second fanout connecting lines, and the plurality of first voltage supply lines away from a base substrate;
wherein an orthographic projection of the anode on a base substrate at least partially overlaps with an orthographic projection of the individual second fanout connecting line on the base substrate; at least partially overlaps with an orthographic projection of the individual first voltage supply line on the base substrate; and at least partially overlaps with an orthographic projection of an individual data line on the base substrate.

4. The array substrate of claim 3, wherein the individual second fanout connecting line, the individual first voltage supply line, and the individual data line are substantially evenly distributed along a first direction with respect to the anode.

5. The array substrate of claim 3, wherein portions of the individual second fanout connecting line, the individual first voltage supply line, and the individual data line, in a region crossing over the anode, have a substantial mirror symmetry with respect to a plane perpendicular to the anode and intersecting the anode.

6. The array substrate of claim 1, further comprising a first data signal connecting pad, a second data signal connecting pad, and a fanout connecting pad;
wherein the individual data line is connected to the second data signal connecting pad through a first pad connecting via;
the individual second fanout connecting line is connected to the fanout connecting pad through a second pad connecting via; and
the second data signal connecting pad is connected to the first data signal connecting pad through a third pad connecting via.

7. The array substrate of claim 6, wherein an orthographic projection of a conductive material extending through the first pad connecting via on a base substrate is substantially non-overlapping with an orthographic projection of a conductive material extending through the third pad connecting via on the base substrate.

8. The array substrate of claim 6, wherein the first pad connecting via has a first elongated shape in a cross-section along a plane having the plurality of data lines, the plurality of first voltage supply lines, and the plurality of second fanout connecting lines;
the second pad connecting via has a second elongated shape in a cross-section along a plane having the plurality of data lines, the plurality of first voltage supply lines, and the plurality of second fanout connecting lines;
the third pad connecting via has a third elongated shape in a cross-section along a plane having the plurality of data lines, the plurality of first voltage supply lines, and the plurality of second fanout connecting lines;
the first elongated shape has a longitudinal side along a direction substantially parallel to a first direction;
the second elongated shape has a longitudinal side along a direction substantially parallel to the first direction; and
the third elongated shape has a longitudinal side along a direction substantially parallel to a second direction.

9. The array substrate of claim 6, further comprising a pixel definition layer;
wherein an orthographic projection of the pixel definition layer on a base substrate covers an orthographic projection of a conductive material extending through the first pad connecting via on the base substrate, and covers an orthographic projection of a conductive material extending through the second pad connecting via on the base substrate.

10. The array substrate of claim 6, further comprising a pixel definition layer defining a plurality of subpixel apertures, and a light emitting layer in the plurality of subpixel apertures;
wherein an orthographic projection of a light emitting material in the plurality of subpixel apertures on a base substrate is substantially non-overlapping with the orthographic projection of a conductive material extending through the first pad connecting via on the base substrate, and is non-overlapping with the orthographic projection of a conductive material extending through the second pad connecting via on the base substrate.

11. The array substrate of claim 1, further comprising an anode, an anode connecting pad, a second relay electrode, and a first relay electrode;
a first anode connecting via, a second anode connecting via, a third anode connecting via, and a fourth anode connecting via; and
a pixel driving circuit comprising a light emitting control transistor;
wherein the anode is connected to the anode connecting pad through the first anode connecting via;
the anode connecting pad is connected to the second relay electrode through the second anode connecting via;
the second relay electrode is connected to the first relay electrode through the third anode connecting via; and
the first relay electrode is connected to a second electrode of the light emitting control transistor through the fourth anode connecting via.

12. The array substrate of claim 11, wherein, in a first adjacent column of pixel driving circuits, the first anode connecting via is spaced apart from the fourth anode connecting via by a first distance along a second direction;
in a second adjacent column of pixel driving circuits, the first anode connecting via is spaced apart from the fourth anode connecting via by a second distance along the second direction; and
the second distance is greater than the first distance by at least 10%.

13. The array substrate of claim 11, wherein, in a first adjacent column of pixel driving circuits, an orthographic projection of the anode on a base substrate substantially covers the orthographic projection of the anode connecting pad on a base substrate, substantially covers the orthographic projection of the second relay electrode on the base substrate, and substantially covers the orthographic projection of the first relay electrode on the base substrate; and
in a second adjacent column of pixel driving circuits, an orthographic projection of the anode on the base substrate partially overlaps with an orthographic projection of the anode connecting pad on the base substrate, is substantially non-overlapping with the orthographic projection of the second relay electrode on the base substrate, and is substantially non-overlapping with the orthographic projection of the first relay electrode on the base substrate.

14. The array substrate of claim 1, further comprising:
in a first adjacent column of pixel driving circuits, a respective reference signal line of a plurality of reference signal lines; and
in a second adjacent column of pixel driving circuits, a respective third reset signal line of a plurality of third reset signal lines;
wherein the plurality of reference signal lines are absent in the second adjacent column of pixel driving circuits; and
the plurality of third reset signal lines are absent in the first adjacent column of pixel driving circuits.

15. The array substrate of claim 14, further comprising a node connecting line in a respective pixel driving circuit;
wherein, in the first adjacent column of pixel driving circuits, the node connecting line is at least partially surrounded by the respective reference signal line.

16. The array substrate of claim 15, wherein, in the first adjacent column of pixel driving circuits, the respective reference signal line comprises a main body extending along a direction substantially parallel to a second direction, and a plurality of first reference signal branches;
a respective first reference signal branch of the plurality of first reference signal branches extends away from the main body;
the respective first reference signal branch comprises a first portion and a second portion;
the first portion connects the second portion with the main body;
the first portion extends along a direction substantially parallel to a first direction;
the second portion extends along a direction substantially parallel to the second direction; and
the node connecting line is at least partially surrounded by the main body on a first side, by the first portion on a second side, and by the second portion on a third side.

17. The array substrate of claim 15, wherein, in the second adjacent column of pixel driving circuits, the node connecting line is at least partially surrounded by the respective third reset signal line on a first side, and at least partially surrounded by a first voltage signal connecting pad on a second side.

18. The array substrate of claim 1, further comprising a plurality of first fanout connecting lines, a second data signal connecting pad, a fanout connecting pad, a first connecting bridge, and a second connecting bridge;
wherein the plurality of data lines comprises a plurality of second data lines;
a respective second data line of the plurality of second data lines is connected to the second data signal connecting pad;
the second data signal connecting pad is connected to the second connecting bridge;
the second connecting bridge is connected to a respective first fanout connecting line of the plurality of first fanout connecting lines;
the respective first fanout connecting line is connected to the first connecting bridge;
the first connecting bridge is connected to a respective second fanout connecting line of the plurality of second fanout connecting lines; and
the respective second fanout connecting line is electrically connected to a data driving circuit.

19. (canceled)

20. An array substrate, comprising:
a plurality of data lines;
a plurality of first fanout connecting lines;
a plurality of second fanout connecting lines; and
a plurality of first voltage supply lines;
wherein, in at least one subpixel of the array substrate, an individual data line of the plurality of data lines and an individual second fanout connecting line of the plurality of second fanout connecting lines have a substantial mirror symmetry with respect to an individual first voltage supply line of the plurality of first voltage supply lines;
the plurality of first fanout connecting lines and the plurality of second fanout connecting lines are substantially in a display area of the array substrate;
the plurality of data lines comprise a plurality of first data lines and a plurality of second data lines;
the plurality of first data lines are connected to a data driving circuit; and
a respective second data line of the plurality of second data lines is connected to the data driving circuit through a respective first fanout connecting line of the plurality of first fanout connecting lines and a respective second fanout connecting line of the plurality of second fanout connecting lines.

21. A display apparatus, comprising the array substrate of claim 1, and one or more integrated circuits connected to the array substrate.
